(19) United States
(12) Patent Application Publication
(10) Pub. No.: US 2026/0206607 A1
(43) Pub. Date: Jul. 16, 2026

(54) SEMICONDUCTOR DEVICE INCLUDING OVERLAY KEY STRUCTURE

(71) Applicant: SAMSUNG ELECTRONICS CO., LTD., Suwon-si (KR)

(72) Inventors: Woohyeok JEONG, Suwon-si (KR); Donghwan KIM, Suwon-si (KR); Heonju LEE, Suwon-si (KR)

(73) Assignee: SAMSUNG ELECTRONICS CO., LTD., Suwon-si (KR)

(21) Appl. No.: 19/447,409

(22) Filed: Jan. 13, 2026

(30) Foreign Application Priority Data
Jan. 15, 2025 (KR) 10-2025-0006410

(51) Int. Cl. H10W 46/00

(52) U.S. Cl. CPC H10W 46/301

(57) ABSTRACT

A semiconductor device includes a substrate, a mold and a pair of overlay key structures. The substrate may include chip regions and a scribe lane region surrounding the chip regions. The mold may be disposed on the scribe lane region of the substrate, and may have insulation layers and sacrificial layers alternately and repeatedly stacked in a first direction perpendicular to an upper surface of the substrate. The pair of overlay key structures may be disposed at opposite sides, respectively, of a center line penetrating through a center of the mold. Each of the pair of overlay key structures may include a lower overlay key structure and an upper overlay key structure. The lower overlay key structure may at least partially penetrate through the mold, and the upper overlay key structure may be disposed on the lower overlay key structure.

### CROSS-REFERENCE TO RELATED APPLICATIONS

This application claims priority under 35 USC § 119 to Korean Patent Application No 10-2025-0006410, filed on Jan. 15, 2025, in the Korean Intellectual Property Office (KIPO), the contents of which are herein incorporated by reference in their entirety.

### TECHNICAL FIELD

The inventive concepts relate to a semiconductor device. More particularly, the inventive concepts relate to a vertical memory device including an overlay key structure.

### DISCUSSION OF RELATED ART

In a method of manufacturing a semiconductor device, the accuracy of the photolithography process directly affects the performance and yield of the semiconductor device. Particularly, overlay keys are essential for ensuring alignment accuracy between layers in the formation of multilayers in the semiconductor device. Conventionally, overlay keys employ simple box-in-box or bar-in-bar structures to measure the alignment state between upper and lower layer patterns. However, as the semiconductor devices continue to scale down, when deformation or damage to the overlay key occurs due to process variations, accurate alignment measurement becomes difficult.

### SUMMARY

Example embodiments provide a semiconductor device having improved reliability.

According to an aspect of the inventive concept, there is provided a semiconductor device. The semiconductor device may include a substrate, a mold and a pair of overlay key structures. The substrate may include chip regions and a scribe lane region surrounding the chip regions. The mold may be disposed on the scribe lane region of the substrate, and may have insulation layers and sacrificial layers alternately and repeatedly stacked in a first direction perpendicular to an upper surface of the substrate. The pair of overlay key structures may be disposed at opposite sides, respectively, of a center line penetrating through a center of the mold. Each of the pair of overlay key structures may include a lower overlay key structure and an upper overlay key structure. The lower overlay key structure may at least partially penetrate through the mold, and the upper overlay key structure may be disposed on the lower overlay key structure.

According to an aspect of the inventive concept, there is provided a semiconductor device. The semiconductor device may include a mold, a pair of lower overlay key structures, and a pair of upper overlay key structures. The mold may be disposed on an overlay key region of a substrate, and may have insulation layers and sacrificial layers alternately and repeatedly stacked in a first direction perpendicular to an upper surface of the substrate. The pair of lower overlay key structures may be disposed in a second direction parallel to an upper surface of the substrate, and each of the pair of lower overlay key structures may at least partially penetrating through the mold. The pair of upper overlay key structures may be disposed in the second direction, corresponding to the pair of lower overlay key structures, respectively, and each of the upper overlay key structures may be disposed on the mold. The pair of lower overlay key structures may include a first lower overlay key structure and a second lower overlay key structure. The first lower overlay key structure may include a first lower overlay key group and a second lower overlay key group. The first lower overlay key group may include first, second, third and fourth lower overlay key sub-groups having 90-degree rotational symmetry in a clockwise direction about a first center point. The second lower overlay key group may include fifth, sixth, seventh and eighth lower overlay key sub-groups having 90-degree rotational symmetry in the clockwise direction about a second center point. The first to fourth lower overlay key sub-groups may be radially arranged to be spaced apart from the first center point by a first distance. The fifth to eighth lower overlay key sub-groups may be radially arranged to be spaced apart from the second center point by a second distance less than the first distance.

According to an aspect of the inventive concept, there is provided a semiconductor device. The semiconductor device may include a substrate, a first mold, a first pair of overlay key structures, a second mold, and a second pair of overlay key structures. The substrate may include shot regions, and each of the shot regions may include a reference shot area and a double exposure area. The first mold may be disposed on the double exposure area of the substrate, and the first mold may have first insulation layers and first sacrificial layers alternately and repeatedly stacked in a first direction perpendicular to an upper surface of the substrate. Each of the first pair of overlay key structures may include a first lower overlay key structure and a first upper overlay key structure. The first lower overlay key structure may at least partially penetrate through the first mold, and the first upper overlay key structure may be disposed on the first lower overlay key structure. The second mold may be disposed on the reference shot area of the substrate, and the second mold may have second insulation layers and second sacrificial layers alternately and repeatedly stacked in the first direction. Each of the second pair of overlay key structures may include a second lower overlay key structure and a second upper overlay key structure. The second lower overlay key structure may at least partially penetrate through the second mold, and the second upper overlay key structure may be disposed on the second lower overlay key structure.

The semiconductor device in accordance with example embodiments may include the mold having the insulation layers and the sacrificial layers alternately and repeatedly stacked, and the lower overlay key structure penetrating through the mold. Due to physical deformation caused by a difference in thermal expansion coefficients between the insulation layers and the sacrificial layers, a mold stress overlay may occur.

In the semiconductor device in accordance with example embodiments, by designing the overlay keys as a pair and measuring multiple overlays from the overlay keys, the mold stress overlay may be identified and removed from the measured overlay, so that the actual overlay may be obtained. Accordingly, precise interlayer alignment may be achieved in the semiconductor device manufacturing processes, so that the reliability of the semiconductor device may be improved.

### BRIEF DESCRIPTION OF THE DRAWINGS

FIGS. 1 to 26 are plan views and cross-sectional views illustrating a method of manufacturing a semiconductor device in accordance with example embodiments.

FIGS. 27 to 37 are enlarged plan views and cross-sectional views illustrating a method of manufacturing a semiconductor device in accordance with example embodiments.

FIG. 38 is an enlarged plan view of an overlay key structure illustrating a method of manufacturing a semiconductor device in accordance with example embodiments.

### DETAILED DESCRIPTION

Hereinafter, a semiconductor device, a method for manufacturing the same, and a mass data storage system including the semiconductor device in accordance with example embodiments will be described in detail with reference to the accompanying drawings. It will be understood that, although the terms “first,” “second,” and/or “third” may be used herein to describe various elements, these elements should not be limited by these terms. These terms are only used to distinguish one element from another element.

In the specification (and not necessarily in the claims), a vertical direction substantially perpendicular to an upper surface of a substrate may be referred to as a first direction D1, and two directions crossing each other among horizontal directions substantially parallel to the upper surface of the substrate may be referred to as second and third directions D2 and D3, respectively. In example embodiments, the second and third directions D2 and D3 may be substantially perpendicular to each other.

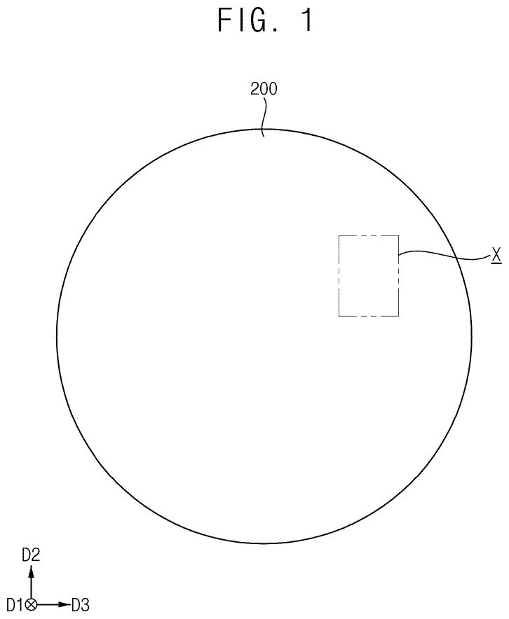

FIGS. 1 to 26 are plan views and cross-sectional views illustrating a method of manufacturing a semiconductor device in accordance with example embodiments.

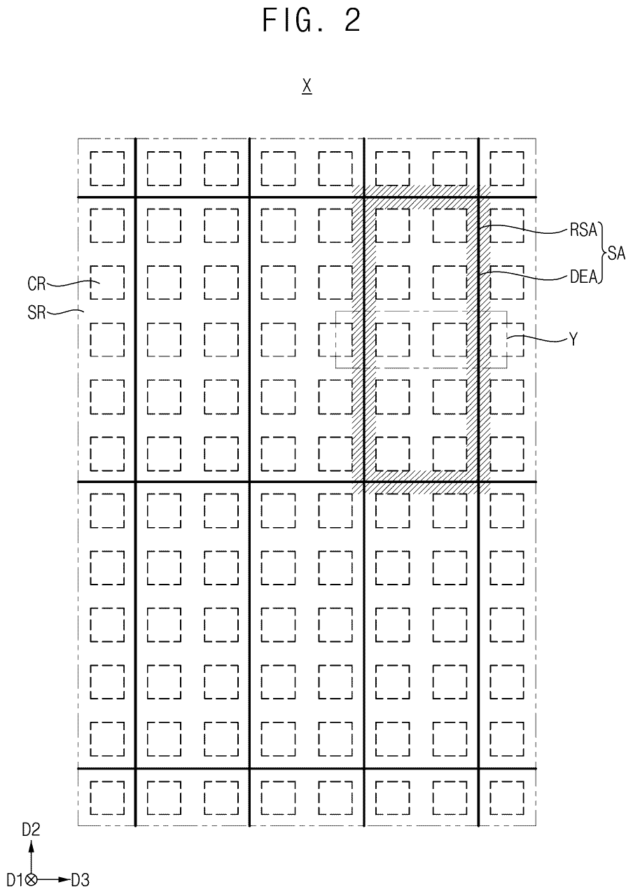

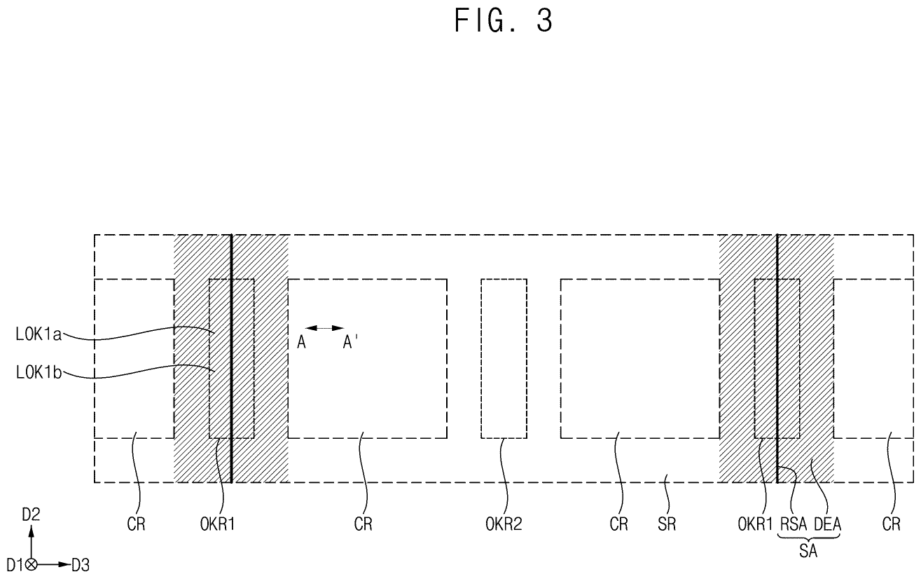

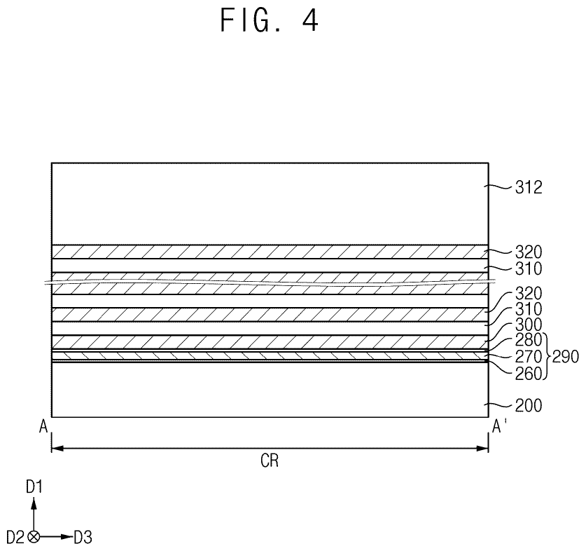

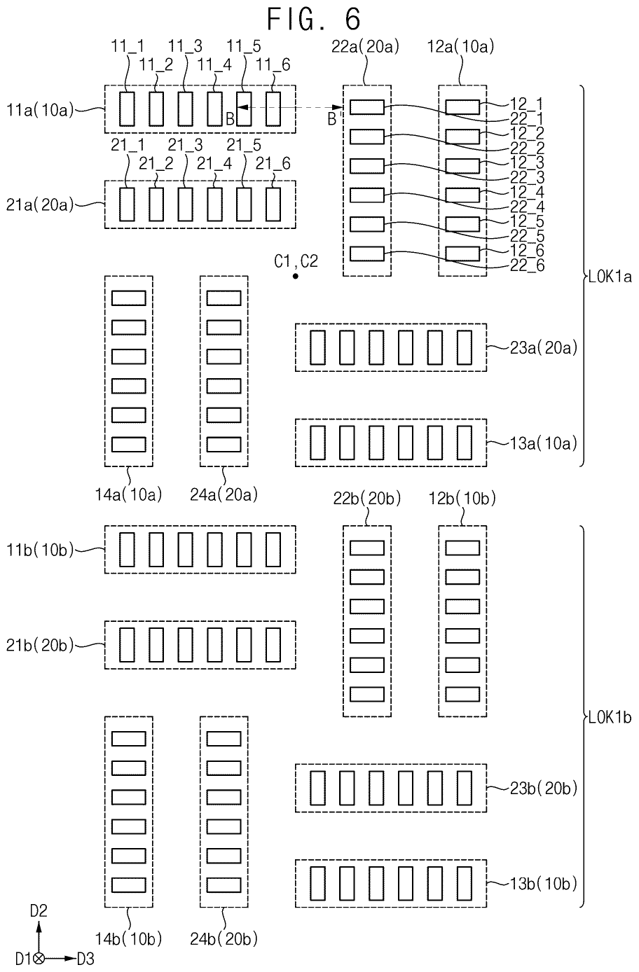

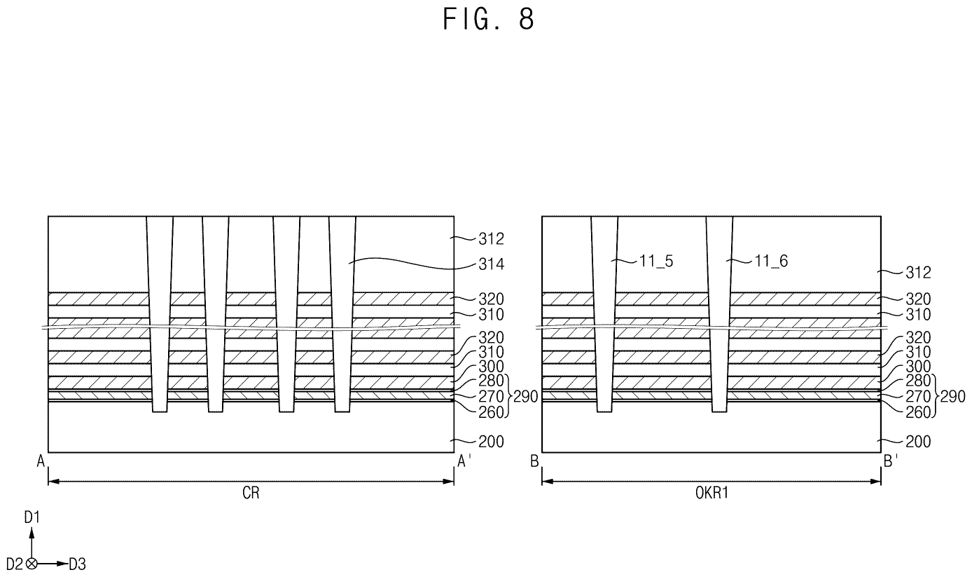

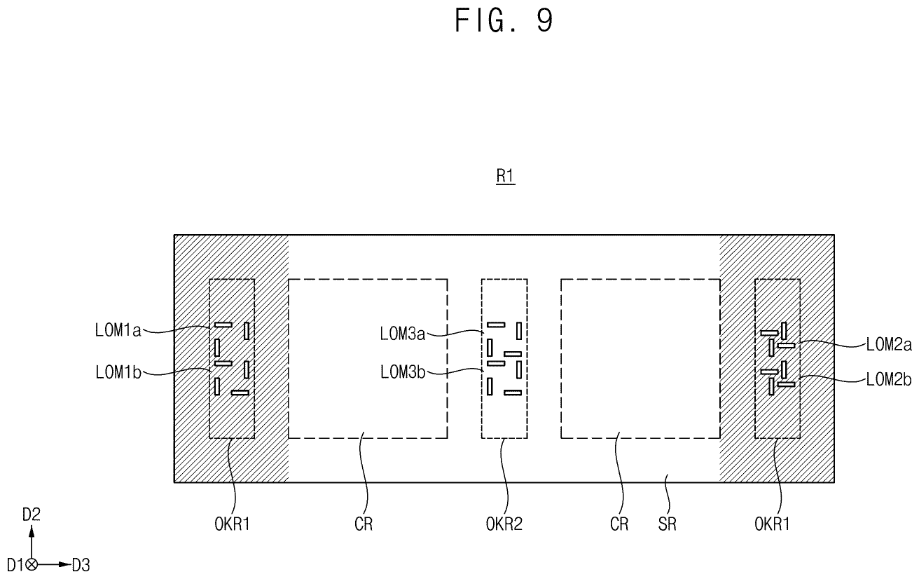

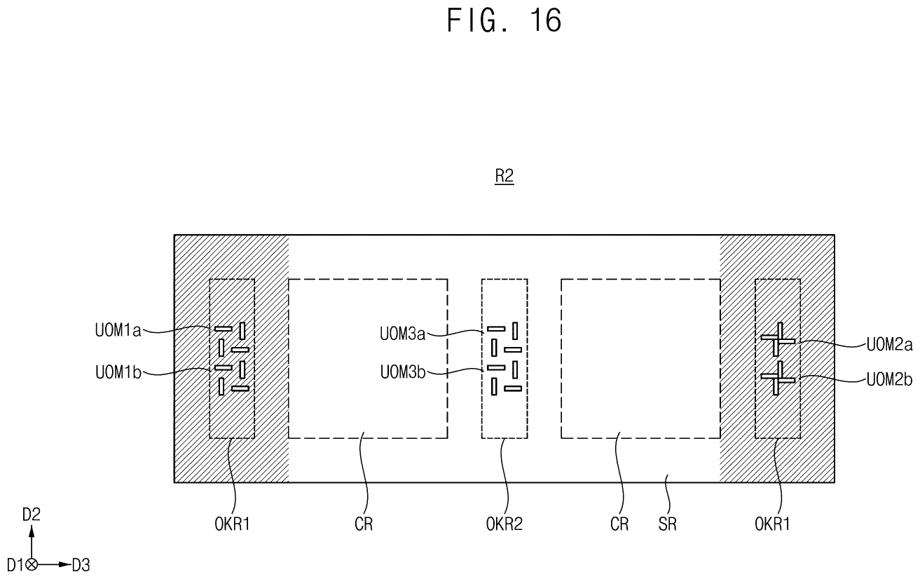

Particularly, FIG. 1 is the plan view, FIG. 2 is an enlarged plan view of region X of FIG. 1. FIGS. 3, 5, 12 and 17 are enlarged plan views of regions Y of corresponding plan views, respectively. FIGS. 4 and 20-26 are cross-sectional views taken along lines A-A′ of corresponding plan views, respectively. Each of FIGS. 8, 10-11 and 15 includes cross-sectional views taken along lines A-A′ and B-B′ of corresponding plan views, respectively. FIGS. 6-7, 13-14, and 18-19 are enlarged plan views illustrating layouts of overlay key structures, and FIGS. 9 and 16 are enlarged plan views illustrating a portion of a reticle.

Referring to FIGS. 1 to 4, a substrate 200 may include a plurality of shot areas SA.

In an exposure process using a reticle, a single shot area SA may refer to an area in which a pattern formed on the reticle is exposed by a single exposure operation, and the plurality of shot areas SA may be formed on the substrate 200 by sequentially moving the reticle and performing the exposure process. Each of the plurality of shot areas SA may include a reference shot area RSA and a double exposure area DEA, which may be formed at a boundary between neighboring ones of the shot areas SA. The double exposure area DEA may denote an area in which exposure is performed twice as exposure operations for adjacent shot areas SA are sequentially performed.

The substrate 200 may include a plurality of chip regions CR and a scribe lane region SR surrounding the plurality of chip regions CR. A semiconductor device may be formed on each of the chip regions CR. The scribe lane region SR may be cut when a dicing process for separating the chip regions CR is performed, and alignment keys, overlay keys, motoring patterns, test patterns may be formed on the scribe lane region SR of the substrate 200. In example embodiments, the chip regions CR may be spaced apart from each other in each of the second and third directions D2 and D3.

In example embodiments, a single shot area SA may include, for example, ten chip regions CR arranged in two columns and five rows, and may include a portion of the scribe lane region SR.

The scribe lane region SR may include a plurality of overlay key regions. First overlay key regions OKR1 among the plurality of overlay key regions may be disposed in the double exposure area DEA of each of the shot areas SA, and second overlay key regions OKR2 among the plurality of overlay key regions may be disposed in the reference shot area RSA of each of the shot areas SA.

A sacrificial layer structure 290 may be formed on the chip regions CR and the first and second overlay key regions OKR1 and OKR2 of the substrate 200, and may be partially removed to form first openings exposing an upper surface of the substrate 200, and a support layer 300 may be formed on the substrate 200 and the sacrificial layer structure 290 to at least partially fill the first openings.

The sacrificial layer structure 290 may include first, second and third sacrificial layers 260, 270 and 280 sequentially stacked in the first direction D1. Each of the first and third sacrificial layers 260 and 280 may include an oxide, e.g., silicon oxide, and the second sacrificial layer 270 may include a nitride, e.g., silicon nitride.

The support layer 300 may include a material, e.g., doped or undoped polysilicon, having an etching selectivity with respect to the first to third sacrificial layers 260, 270 and 280. The support layer 300 may have a uniform thickness, and thus a first recess may be formed on a portion of the support layer 300 in each of the first openings. Hereinafter, a portion of the support layer 300 in each of the first openings may be referred to as a support pattern.

A first insulation layer 310 may be formed on the support layer 300 to fill the first recess, and a planarization process may be performed on an upper portion of the first insulation layer 310. The planarization process may include, e.g., a chemical mechanical polishing (CMP) process and/or an etch back process.

Fourth sacrificial layers 320 and additional first insulation layers 310 may be alternately and repeatedly stacked on the first insulation layer 310, and thus first, second and third lower mold layer structures may be formed on the first overlay key region OKR1, the second overlay key region OKR2 and the chip region CR, respectively, of the substrate 200.

In example embodiments, the first lower mold layer structure may be disposed at a constant distance from the chip regions CR that are adjacent to the first lower mold layer in the third direction D3, and the second lower mold layer structure may be disposed at a constant distance from the chip regions CR that are adjacent to the second lower mold layer in the third direction D3. In example embodiments, each of the first to third lower mold layer structures may have a shape of, e.g., a rectangle.

The first insulation layer 310 may include an oxide, e.g., silicon oxide, and the fourth sacrificial layer 320 may include a material, e.g., a nitride such as silicon nitride, having an etching selectivity with respect to the first insulation layers 310.

A second insulation layer 312 may be formed on the first to third lower mold layer structures. In example embodiments, a thickness in the first direction D1 of the second insulation layer 312 may be greater than a thickness in the first direction D1 of each of the first insulation layers 310.

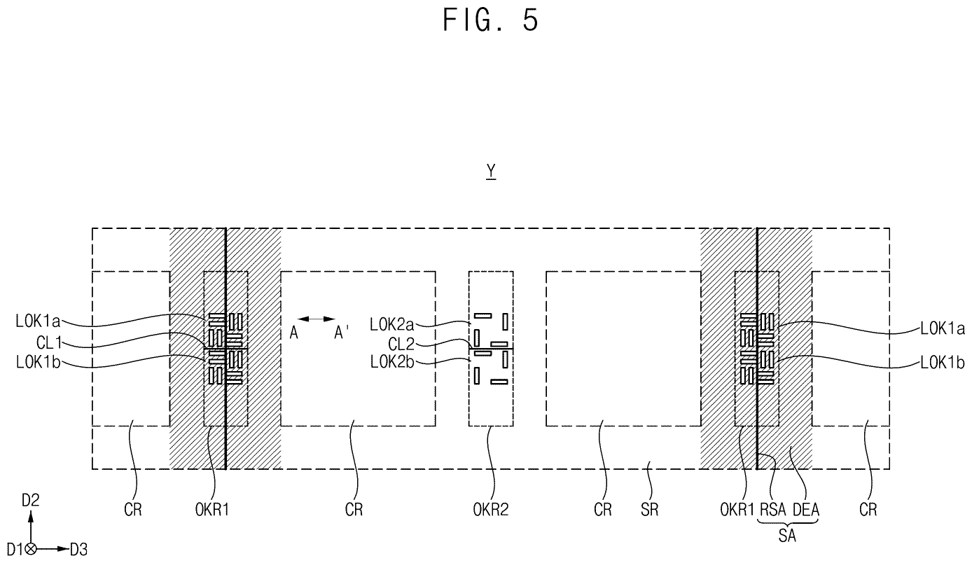

Referring to FIGS. 5 to 9, a sacrificial filler 314 may be formed on the chip region CR, a pair of first lower overlay key structures LOK1a and LOK1b may be formed on the first overlay key region R1, and a pair of second lower overlay key structures LOK2a and LOK2b may be formed on the second overlay key region R2.

In example embodiments, upper surfaces of the sacrificial filler 314, the pair of first lower overlay key structures LOK1a and LOK1b, and the pair of second lower overlay key structures LOK2a and LOK2b may be substantially coplanar with each other.

The sacrificial filler 314, the pair of first lower overlay key structures LOK1a and LOK1b, and the pair of second lower overlay key structures LOK2a and LOK2b may include, e.g., polysilicon, a metal and a carbon-based material, respectively.

In example embodiments, the sacrificial filler 314 may extend through the third lower mold layer structure in the first direction D1, and a plurality of sacrificial fillers 314 may be spaced apart from each other in each of the second and third directions D2 and D3.

The pair of first lower overlay key structures LOK1a and LOK1b may be disposed at opposite sides, respectively, of a first center line CL1 that passes through a center of the first lower mold layer structure and extends in the third direction D3.

Components of the pair of first lower overlay key structures LOK1a and LOK1b, respectively, which may include e.g., lower overlay key patterns, may be arranged by the same layout. Hereinafter, only the first lower overlay key structure LOK1a is described.

The first lower overlay key structure LOK1a may include first and second lower overlay key groups 10a and 20a (refer to FIG. 6). The first lower overlay key group 10a may be radially arranged while being spaced apart from a first center point C1 by a first distance, and the second lower overlay key group 20a may be radially arranged while being spaced apart from a second center point C2 by a second distance smaller than the first distance.

The first lower overlay key group 10a may include first, second, third and fourth lower overlay key sub-groups 11a, 12a, 13a and 14a. The first, second, third and fourth lower overlay key sub-groups 11a, 12a, 13a and 14a may be arranged to be rotated by 90 degrees in a clockwise direction about the first center point C1. That is, the first lower overlay key group 10a may have 90-degree rotational symmetry.

In example embodiments, the first lower overlay key sub-group 11a may include first-1, first-2, first-3, first-4, first-5 and first-6 lower overlay key patterns 11_1, 11_2, 11_3, 11_4, 11_5 and 11_6. Each of the first-1, first-2, first-3, first-4, first-5 and first-6 lower overlay key patterns 11_1, 11_2, 11_3, 11_4, 11_5 and 11_6 may extend in the second direction D2, and the first-1, first-2, first-3, first-4, first-5 and first-6 lower overlay key patterns 11_1, 11_2, 11_3, 11_4, 11_5 and 11_6 may be spaced apart from each other in the third direction D3.

In example embodiments, the second lower overlay key sub-group 12a may include second-1, second-2, second-3, second-4, second-5 and second-6 lower overlay key patterns 12_1, 12_2, 12_3, 12_4, 12_5 and 12_6. The second lower overlay key sub-group 12a may be disposed to be rotated by 90 degrees in a clockwise direction with respect to the first lower overlay key sub-group 11a about the first center point C1. For example, referring to FIG. 6, the second-1, second-2, second-3, second-4, second-5 and second-6 lower overlay key patterns 12_1, 12_2, 12_3, 12_4, 12_5 and 12_6 may be disposed to be rotated by 90 degrees in a clockwise direction with respect to the first-1, first-2, first-3, first-4, first-5 and first-6 lower overlay key patterns 11_1, 11_2, 11_3, 11_4, 11_5 and 11_6, respectively, about the first center point C1.

The third lower overlay key sub-group 13a may be disposed to be rotated by 90 degrees in a clockwise direction with respect to the second lower overlay key sub-group 12a about the first center point C1.

The fourth lower overlay key sub-group 14a may be disposed to be rotated by 90 degrees in a clockwise direction with respect to the third lower overlay key sub-group 13a about the first center point C1.

The second lower overlay key group 20a may include fifth, sixth, seventh and eighth lower overlay key sub-groups 21a, 22a, 23a and 24a. The fifth, sixth, seventh and eighth lower overlay key sub-groups 21a, 22a, 23a and 24a may be arranged to be rotated by 90 degrees in a clockwise direction about the second center point C2. That is, the second lower overlay key group 20a may have 90-degree rotational symmetry.

The first to fourth lower overlay key sub-groups 11a, 12a, 13a and 14a of the first lower overlay key group 10a may be radially arranged from the second center point C2, and may be arranged at a greater distance from the second center point C2 than the fifth to eighth overlay key sub-groups 21a, 22a, 23a and 24a, respectively, of the second lower overlay key group 20a.

The fifth lower overlay key sub-group 21a may be spaced apart from the first lower overlay key sub-group 11a in the second direction D2, and may be disposed closer to the second center point C2 than the first lower overlay key sub-group 11a. In example embodiments, the fifth lower overlay key sub-group 21a may include fifth-1, fifth-2, fifth-3, fifth-4, fifth-5 and fifth-6 lower overlay key patterns 21_1, 21_2, 21_3, 21_4, 21_5 and 21_6. Each of the fifth-1, fifth-2, fifth-3, fifth-4, fifth-5 and fifth-6 lower overlay key patterns 21_1, 21_2, 21_3, 21_4, 21_5 and 21_6 may extend in the second direction D2, and the fifth-1, fifth-2, fifth-3, fifth-4, fifth-5 and fifth-6 lower overlay key patterns 21_1, 21_2, 21_3, 21_4, 21_5 and 21_6 may be spaced apart from each other in the third direction D3.

The sixth lower overlay key sub-group 22a may be spaced apart from the second lower overlay key sub-group 12a in the third direction D3, and may be disposed closer to the second center point C2 than the second lower overlay key sub-group 12a. In example embodiments, the sixth lower overlay key sub-group 22a may include sixth-1, sixth-2, sixth-3, sixth-4, sixth-5 and sixth-6 lower overlay key patterns 22_1, 22_2, 22_3, 22_4, 22_5 and 22_6, and may be disposed to be rotated by 90 degrees in a clockwise direction with respect to the fifth lower overlay key sub-group 21a about the second center point C2. For example, referring to FIG. 6, the sixth-1, sixth-2, sixth-3, sixth-4, sixth-5 and sixth-6 lower overlay key patterns 22_1, 22_2, 22_3, 22_4, 22_5 and 22_6 of the sixth lower overlay key sub-group 22a may be disposed to be rotated by 90 degrees in a clockwise direction with respect to the fifth-1, fifth-2, fifth-3, fifth-4, fifth-5 and fifth-6 lower overlay key patterns 21_1, 21_2, 21_3, 21_4, 21_5 and 21_6, respectively, of the fifth lower overlay key sub-group 21a about the second center point C2.

The seventh lower overlay key sub-group 23a may be disposed to be rotated by 90 degrees in a clockwise direction with respect to the sixth lower overlay key sub-group 22a about the second center point C2.

The eighth lower overlay key sub-group 24a may be disposed to be rotated by 90 degrees in a clockwise direction with respect to the seventh lower overlay key sub-group 23a about the second center point C2.

In FIG. 6, a case in which the first lower overlay key group 10a and the second lower overlay key group 20a are ideally aligned with each other such that the first center point C1 coincides with the second center point C2 is illustrated.

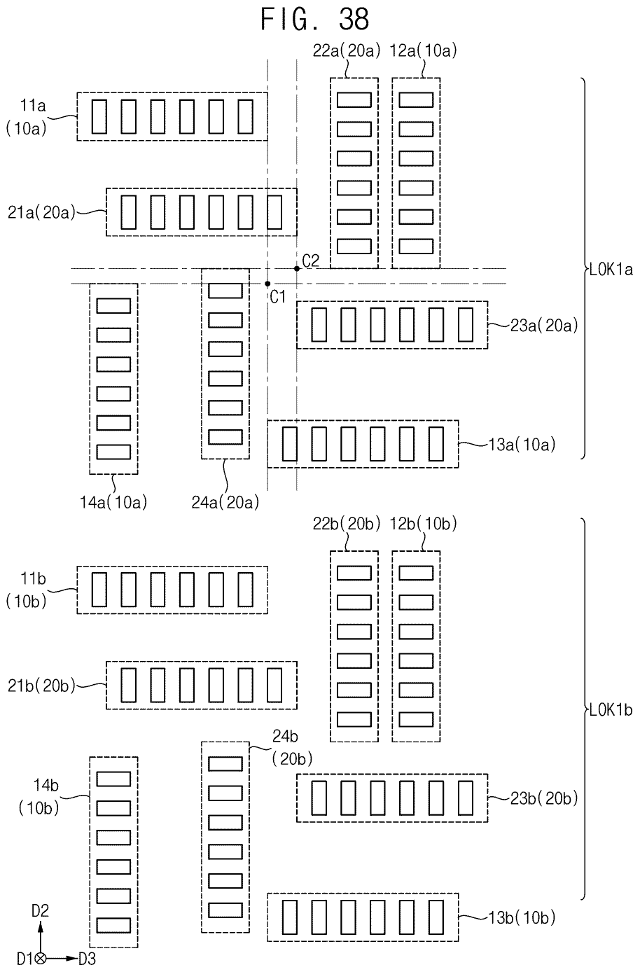

However, for example, the first lower overlay key group 10a may be formed by an exposure process using a first lower mark group LOM1a disposed at a left edge of a first reticle R1, and the second lower overlay key group 20a may be formed by an exposure process using a second lower mark group LOM2a disposed at a right edge of the first reticle R1. That is, the first and second overlay key groups 10a and 20a may be formed by independent exposure processes, and thus, in some cases, the first center point C1 and the second center point C2 may not coincide with each other, but may be offset to each other (refer to FIG. 38).

As illustrated above, the layouts of the lower overlay key patterns included in the pair of second lower overlay key structures LOK2a and LOK2b, respectively, may be substantially the same as each other. Particularly, layouts of the lower overlay key patterns included in third lower overlay key groups 30b of the second lower overlay key structure LOK2b may be substantially the same as layouts of the lower overlay key patterns included in third lower overlay key groups 30a of the second lower overlay key structure LOK2a. The expression “substantially the same” or “substantially identical” may mean that two structures or two layouts are the same, or the two structures or the two layouts are almost the same but with some variation due to an unperfect process or a margin, an error, or a tolerance in manufacturing or measurement. Such a margin, an error, or a tolerance may occur in a photolithography process followed by an etching process, recognized by those of skill in the art.

A pair of first lower overlay key groups 10a and 10b may be formed by an exposure process using a pair of first lower overlay mark groups LOM1a and LOM1b disposed at a left edge of the first reticle R1 shown in FIG. 9, and a pair of second lower overlay key groups 20a and 20b may be formed by an exposure process using a pair of second lower overlay mark groups LOM2a and LOM2b disposed at a right edge of the first reticle R1 shown in FIG. 9.

The pair of second lower overlay key structures LOK2a and LOK2b may be disposed at opposite sides, respectively, of a second center line CL2 that passes through a center of the second lower mold layer structure and extends in the third direction D3.

Components of the pair of second lower overlay key structures LOK2a and LOK2b, respectively, which may include e.g., lower overlay key patterns, may be arranged by the same layout. Hereinafter, only the second lower overlay key structure LOK2a is described.

The second lower overlay key structure LOK2a may include a third lower overlay key group 30a, and the third lower overlay key group 30a may include ninth, tenth, eleventh and twelfth lower overlay key sub-groups 31a, 32a, 33a and 34a. The ninth to twelfth lower overlay key sub-groups 31a, 32a, 33a and 34a may be disposed to be rotated by 90 degrees in a clockwise direction about a third center point C3. That is, the third lower overlay key group 30a may have 90-degree rotational symmetry.

In example embodiments, the ninth lower overlay key sub-group 31a may include ninth-1, ninth-2, ninth-3, ninth-4, ninth-5 and ninth-6 lower overlay key patterns 31_1, 31_2, 31_3, 31_4, 31_5 and 31_6. Each of the ninth-1, ninth-2, ninth-3, ninth-4, ninth-5 and ninth-6 lower overlay key patterns 31_1, 31_2, 31_3, 31_4, 31_5 and 31_6 may extend in the second direction D2, and the ninth-1, ninth-2, ninth-3, ninth-4, ninth-5 and ninth-6 lower overlay key patterns 31_1, 31_2, 31_3, 31_4, 31_5 and 31_6 may be spaced apart from each other in the third direction D3.

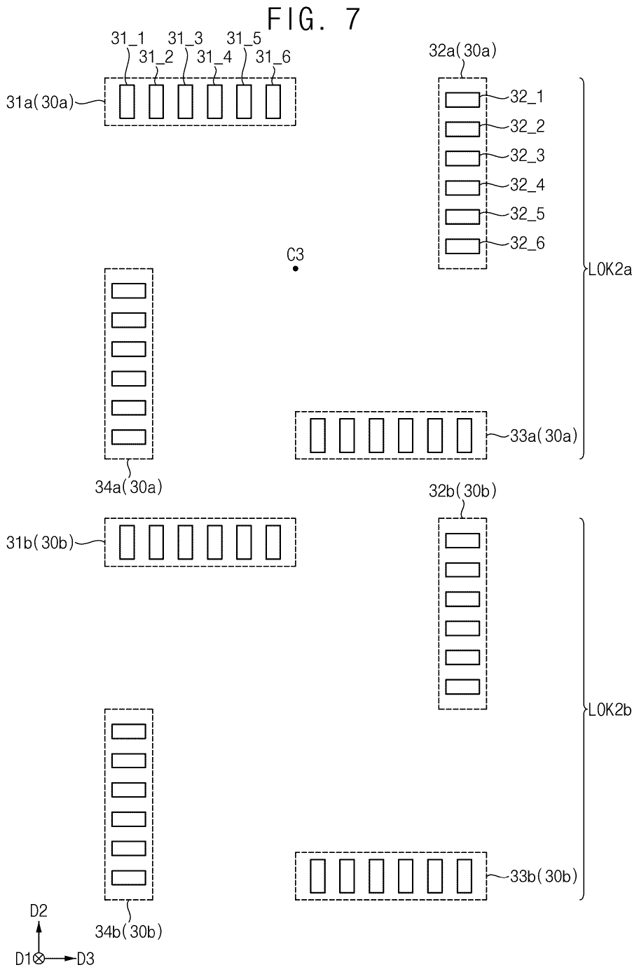

In example embodiments, the tenth lower overlay key sub-group 32a may include tenth-1, tenth-2, tenth-3, tenth-4, tenth-5 and tenth-6 lower overlay key patterns 32_1, 32_2, 32_3, 32_4, 32_5 and 32_6. The tenth lower overlay key sub-group 32a may be disposed to be rotated by 90 degrees in a clockwise direction with respect to the ninth lower overlay key sub-group 31a about the third center point C3. For example, referring to FIG. 7, the tenth-1, tenth-2, tenth-3, tenth-4, tenth-5 and tenth-6 lower overlay key patterns 32_1, 32_2, 32_3, 32_4, 32_5 and 32_6 may be disposed to be rotated by 90 degrees in a clockwise direction with respect to the ninth-1, ninth-2, ninth-3, ninth-4, ninth-5 and ninth-6 lower overlay key patterns 31_1, 31_2, 31_3, 31_4, 31_5 and 31_6, respectively, about the third center point C3.

The eleventh lower overlay key sub-group 33a may be disposed to be rotated by 90 degrees in a clockwise direction with respect to the tenth lower overlay key sub-group 32a about the third center point C3.

The twelfth lower overlay key sub-group 34a may be disposed to be rotated by 90 degrees in a clockwise direction with respect to the eleventh lower overlay key sub-group 33a about the third center point C3.

As illustrated above, the layouts of the lower overlay key patterns included in the pair of second lower overlay key structures LOK2a and LOK2b, respectively, may be substantially the same as each other. Particularly, layouts of the lower overlay key patterns included in third lower overlay key groups 30b of the second lower overlay key structure LOK2b may be substantially the same as layouts of the lower overlay key patterns included in third lower overlay key groups 30a of the second lower overlay key structure LOK2a.

A pair of third lower overlay key groups 30a and 30b may be formed by an exposure process using a pair of third lower overlay mark groups LOM3a and LOM3b disposed at a center of the first reticle R1.

The number of the lower overlay key patterns included in each of the lower overlay key sub-groups may not be limited.

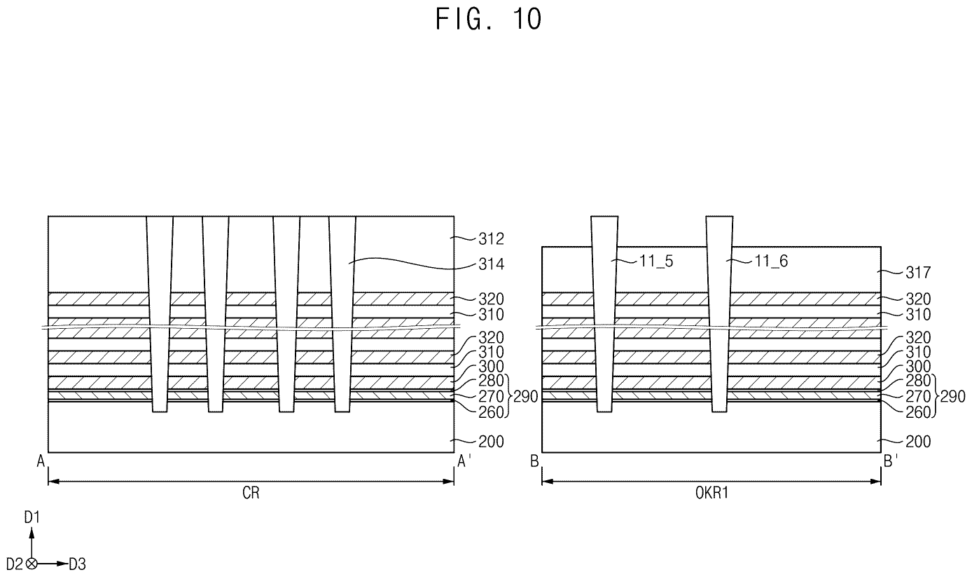

Referring to FIG. 10, an upper portion of the second insulation layer 312 of the first and second lower mold layer structures that are disposed on the first and second overlay key regions OKR1 and OKR2 of the substrate 200 may be removed.

Thus, the second insulation layer 312 of the first and second lower mold layer structures may be transformed into a third insulation layer 317, and upper sidewalls of the pair of first lower overlay key structures LOK1a and LOK1b and upper sidewalls of the pair of second lower overlay key structures LOK2a and LOK2b may be exposed.

An upper surface of the third insulation layer 317 may be lower than the upper surface of the second insulation layer 312, the pair of first lower overlay key structures LOK1a and LOK1b, and the pair of second lower overlay key structures LOK2a and LOK2b.

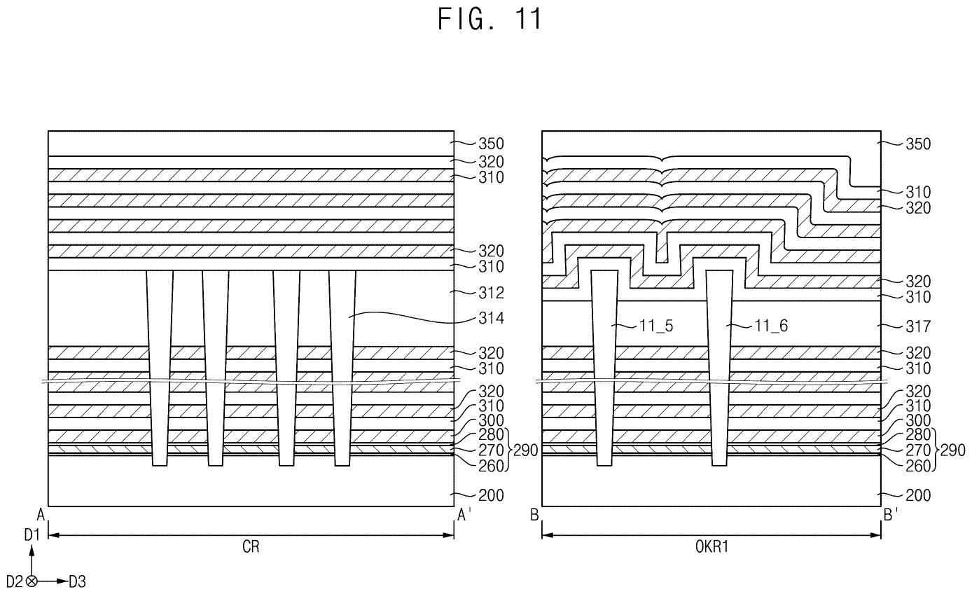

Referring to FIG. 11, the first insulation layers 310 and the fourth sacrificial layers 320 may be alternately and repeatedly stacked on the second and third insulation layers 312 and 317, the pair of first lower overlay key structures LOK1a and LOK1b, and the pair of second lower overlay key structures LOK2a and LOK2b.

A first insulating interlayer 350 may be formed on an uppermost one of the first insulation layers 320, and a planarization process may be performed on an upper portion of the first insulating interlayer 350. Thus, first, second and third mold layer structures may be formed on the first, second and third lower mold layer structures, respectively.

The first insulating interlayer 350 may include an oxide, e.g., silicon oxide.

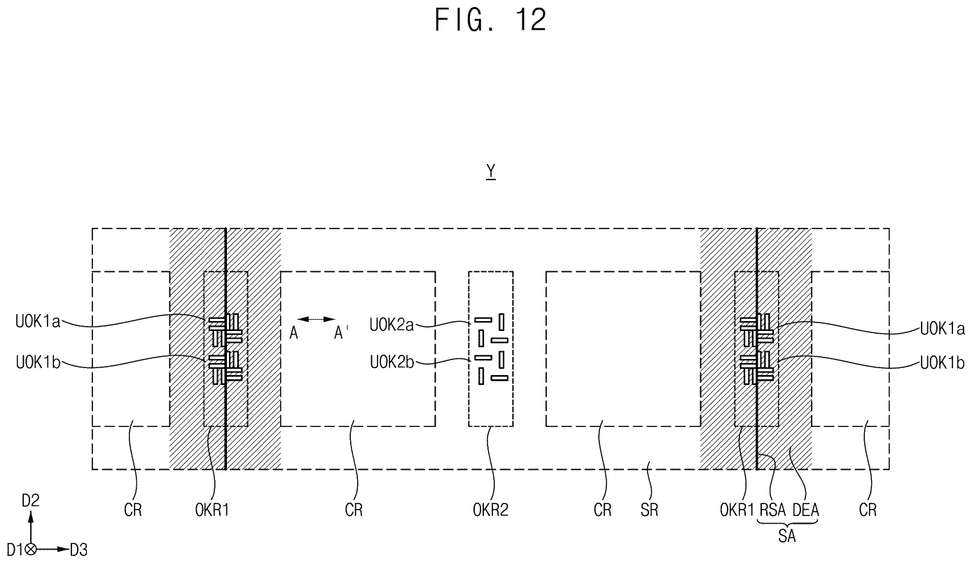

Referring to FIGS. 12 to 16, a mold 400 and an anti-reflection layer 410 may be sequentially formed on the substrate 200.

The mold 400 may include, e.g., spin-on hardmask (SOH), and the anti-reflection layer 410 may include, e.g., silicon oxynitride.

A photoresist pattern 411, a pair of first upper overlay key structures UOK1a and UOK1b, and a pair of second upper overlay key structures UOK2a and UOK2b may be formed. Particularly, the photoresist pattern 411 may be formed on the chip region CR of the substrate 200, the pair of first upper overlay key structures UOK1a and UOK1b may be formed on the first overlay key region OKR1 of the substrate 200, and the pair of second upper overlay key structures UOK2a and UOK2b may be formed on the second overlay key region OKR2 of the substrate 200.

The photoresist pattern 411, upper overlay key patterns included in the pair of first upper overlay key structures UOK1a and UOK1b, and upper overlay key patterns included in the pair of second upper overlay key structures UOK2a and UOK2b may include, e.g., photoresist material.

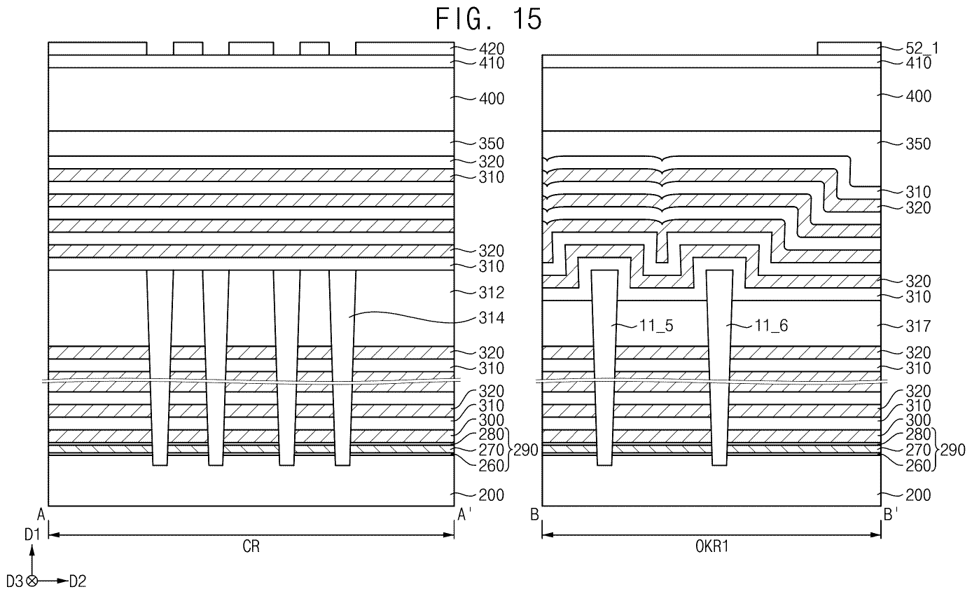

The photoresist pattern 411 may serve as an etching mask for forming various structures on the chip region CR, and in FIG. 15, the photoresist pattern 411 may serve as an etching mask for forming a channel hole.

The pair of first upper overlay key structures UOK1a and UOK1b may be disposed at opposite sides, respectively, of the first center line CL1.

Components of the pair of first upper overlay key structures UOK1a and UOK1b, respectively, which may include e.g., upper overlay key patterns, may be arranged by the same layout. Hereinafter, only the first upper overlay key structure UOK1a is described.

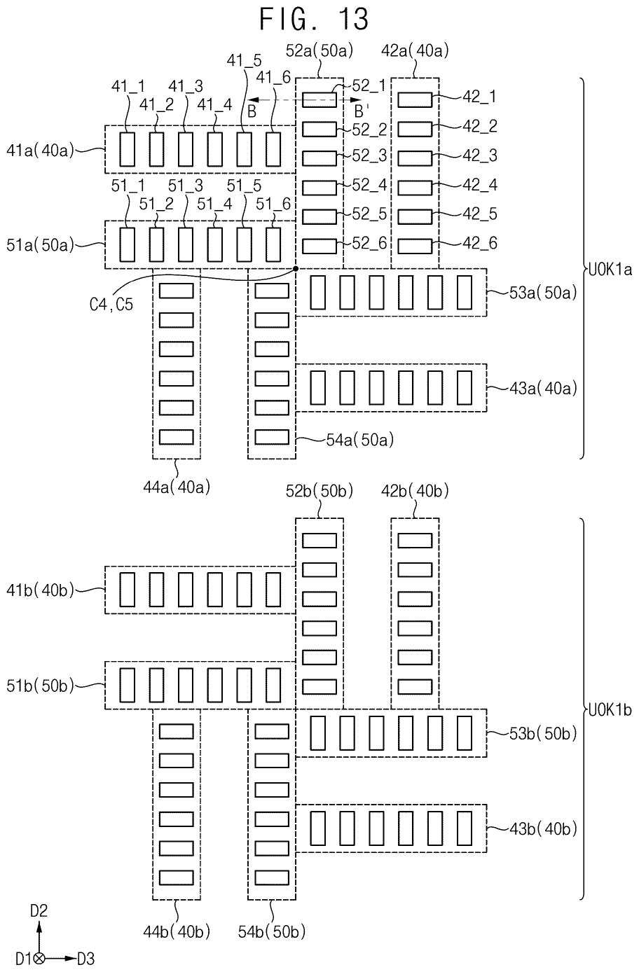

The first upper overlay key structure UOK1a may include first and second upper overlay key groups 40a and 50a (refer to FIG. 13). The first upper overlay key group 40a may be radially arranged while being spaced apart from a fourth center point C4 by a third distance, and the second upper overlay key group 50a may be radially arranged while being spaced apart from a fifth center point C5 by a fourth distance smaller than the third distance.

The first upper overlay key group 40a may include first, second, third and fourth upper overlay key sub-groups 41a, 42a, 43a and 44a. The first, second, third and fourth upper overlay key sub-groups 41a, 42a, 43a and 44a may be arranged to be rotated by 90 degrees in a clockwise direction about the fourth center point C4. That is, the first upper overlay key group 40a may have 90-degree rotational symmetry.

In example embodiments, the first upper overlay key sub-group 41a may include first-1, first-2, first-3, first-4, first-5 and first-6 upper overlay key patterns 41_1, 41_2, 41_3, 41_4, 41_5 and 41_6. Each of the first-1, first-2, first-3, first-4, first-5 and first-6 upper overlay key patterns 41_1, 41_2, 41_3, 41_4, 41_5 and 41_6 may extend in the second direction D2, and the first-1, first-2, first-3, first-4, first-5 and first-6 upper overlay key patterns 41_1, 41_2, 41_3, 41_4, 41_5 and 41_6 may be spaced apart from each other in the third direction D3.

In example embodiments, the second upper overlay key sub-group 42a may include second-1, second-2, second-3, second-4, second-5 and second-6 upper overlay key patterns 42_1, 42_2, 42_3, 42_4, 42_5 and 42_6. The second upper overlay key sub-group 42a may be disposed to be rotated by 90 degrees in a clockwise direction with respect to the first upper overlay key sub-group 41a about the fourth center point C4. For example, referring to FIG. 13, the second-1, second-2, second-3, second-4, second-5 and second-6 upper overlay key patterns 42_1, 42_2, 42_3, 42_4, 42_5 and 42_6 may be disposed to be rotated by 90 degrees in a clockwise direction with respect to the first-1, first-2, first-3, first-4, first-5 and first-6 upper overlay key patterns 41_1, 41_2, 41_3, 41_4, 41_5 and 41_6, respectively, about the fourth center point C4.

The third upper overlay key sub-group 43a may be disposed to be rotated by 90 degrees in a clockwise direction with respect to the second upper overlay key sub-group 42a about the fourth center point C4.

The fourth upper overlay key sub-group 44a may be disposed to be rotated by 90 degrees in a clockwise direction with respect to the third upper overlay key sub-group 43a about the fourth center point C4.

The second upper overlay key group 50a may include fifth, sixth, seventh and eighth upper overlay key sub-groups 51a, 52a, 53a and 54a. The fifth, sixth, seventh and eighth lower overlay key sub-groups 51a, 52a, 53a and 54a may be arranged to be rotated by 90 degrees in a clockwise direction about the fifth center point C5. That is, the second upper overlay key group 50a may have 90-degree rotational symmetry.

The first to fourth upper overlay key sub-groups 41a, 42a, 43a and 44a of the first upper overlay key group 40a may be radially arranged about the fifth center, and may be arranged at a greater distance from the fifth center point C5 than the fifth to eighth upper overlay key sub-groups 51a, 52a, 53a and 54a, respectively, of the second upper overlay key group 50a.

The fifth upper overlay key sub-group 51a may be spaced apart from the first upper overlay key sub-group 41a in the second direction D2, and may be disposed closer to the fifth center point C5 than the first upper overlay key sub-group 41a. In example embodiments, the fifth upper overlay key sub-group 51a may include fifth-1, fifth-2, fifth-3, fifth-4, fifth-5 and fifth-6 upper overlay key patterns 51_1, 51_2, 51_3, 51_4, 51_5 and 51_6. Each of the fifth-1, fifth-2, fifth-3, fifth-4, fifth-5 and fifth-6 upper overlay key patterns 51_1, 51_2, 51_3, 51_4, 51_5 and 51_6 may extend in the second direction D2, and the fifth-1, fifth-2, fifth-3, fifth-4, fifth-5 and fifth-6 upper overlay key patterns 51_1, 51_2, 51_3, 51_4, 51_5 and 51_6 may be spaced apart from each other in the third direction D3.

The sixth upper overlay key sub-group 52a may be spaced apart from the second upper overlay key sub-group 42a in the third direction D3, and may be disposed closer to the fifth center point C5 than the second upper overlay key sub-group 42a. In example embodiments, the sixth upper overlay key sub-group 52a may include sixth-1, sixth-2, sixth-3, sixth-4, sixth-5 and sixth-6 upper overlay key patterns 52_1, 52_2, 52_3, 52_4, 52_5 and 52_6, and may be disposed to be rotated by 90 degrees in a clockwise direction with respect to the fifth upper overlay key sub-group 51a about the fifth center point C5. For example, referring to FIG. 13, the sixth-1, sixth-2, sixth-3, sixth-4, sixth-5 and sixth-6 upper overlay key patterns 52_1, 52_2, 52_3, 52_4, 52_5 and 52_6 of the sixth upper overlay key sub-group 52a may be disposed to be rotated by 90 degrees in a clockwise direction with respect to the fifth-1, fifth-2, fifth-3, fifth-4, fifth-5 and fifth-6 upper overlay key patterns 51_1, 51_2, 51_3, 51_4, 51_5 and 51_6, respectively, of the fifth upper overlay key sub-group 51a about the fifth center point C5.

The seventh upper overlay key sub-group 53a may be disposed to be rotated by 90 degrees in a clockwise direction with respect to the sixth upper overlay key sub-group 52a about the fifth center point C5.

The eighth upper overlay key sub-group 54a may be disposed to be rotated by 90 degrees in a clockwise direction with respect to the seventh upper overlay key sub-group 53a about the fifth center point C5.

In FIG. 13, a case in which the first upper overlay key group 40a and the second upper overlay key group 50a are ideally aligned with each other such that the fourth center point C4 coincides with the fifth center point C5 is illustrated.

However, for example, the first upper overlay key group 40a may be formed by an exposure process using a first upper mark group UOM1a disposed at a left edge of a second reticle R2, and the second upper overlay key group 50a may be formed by an exposure process using a second upper lower mark group UOM2a disposed at a right edge of the second reticle R2. That is, the first and second upper overlay key groups 40a and 50a may be formed by independent exposure processes, and thus, in some cases, the fourth center point C4 and the fifth center point C5 may not coincide with each other, but may be offset to each other.

As illustrated above, the layouts of the upper overlay key patterns included in the pair of first upper overlay key structures UOK1a and UOK1b, respectively, may be substantially the same as each other. Particularly, layouts of the upper overlay key patterns included in first and second upper overlay key groups 40b and 50b of the first upper overlay key structure UOK1b may be substantially the same as layouts of the lower overlay key patterns included in first and second upper overlay key groups 40a and 50a of the first upper overlay key structure UOK1a.

A pair of first upper overlay key groups 40a and 40b may be formed by an exposure process using a pair of first upper overlay mark groups UOM1a and UOM1b disposed at a left edge of the second reticle R2, and a pair of second upper overlay key groups 50a and 50b may be formed by an exposure process using a pair of second upper overlay mark groups UOM2a and UOM2b disposed at a right edge of the second reticle R2.

The pair of second upper overlay key structures UOK2a and UOK2b may be disposed at opposite sides, respectively, of the second center line CL2.

The pair of second upper overlay key structures UOK2a and UOK2b may include a third upper overlay key group 60a, and the third upper overlay key group 60a may include ninth, tenth, eleventh and twelfth upper overlay key sub-groups 61a, 62a, 63a and 64a. The ninth to twelfth upper overlay key sub-groups 61a, 62a, 63a and 64a may be disposed to be rotated by 90 degrees in a clockwise direction about a sixth center point C6. That is, the third upper overlay key group 60a may have 90-degree rotational symmetry.

In example embodiments, the ninth upper overlay key sub-group 61a may include ninth-1, ninth-2, ninth-3, ninth-4, ninth-5 and ninth-6 upper overlay key patterns 61_1, 61_2, 61_3, 61_4, 61_5 and 61_6. Each of the ninth-1, ninth-2, ninth-3, ninth-4, ninth-5 and ninth-6 upper overlay key patterns 61_1, 61_2, 61_3, 61_4, 61_5 and 61_6 may extend in the second direction D2, and the ninth-1, ninth-2, ninth-3, ninth-4, ninth-5 and ninth-6 upper overlay key patterns 61_1, 61_2, 61_3, 61_4, 61_5 and 61_6 may be spaced apart from each other in the third direction D3.

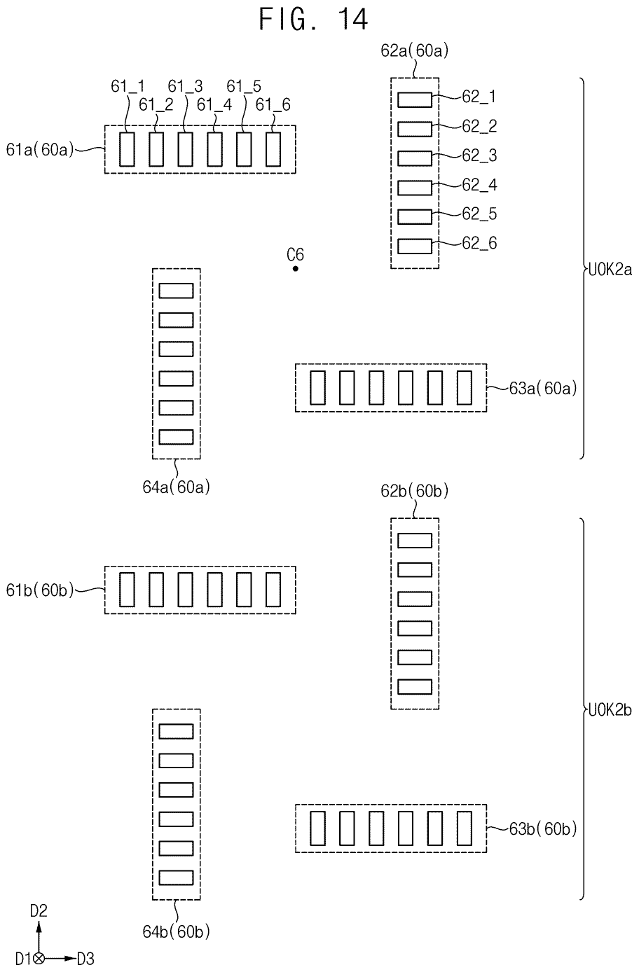

In example embodiments, the tenth upper overlay key sub-group 62a may include tenth-1, tenth-2, tenth-3, tenth-4, tenth-5 and tenth-6 upper overlay key patterns 62_1, 62_2, 62_3, 62_4, 62_5 and 62_6. The tenth upper overlay key sub-group 62a may be disposed to be rotated by 90 degrees in a clockwise direction with respect to the ninth upper overlay key sub-group 61a about the sixth center point C6. For example, referring to FIG. 14, the tenth-1, tenth-2, tenth-3, tenth-4, tenth-5 and tenth-6 upper overlay key patterns 62_1, 62_2, 62_3, 62_4, 62_5 and 62_6 may be disposed to be rotated by 90 degrees in a clockwise direction with respect to the ninth-1, ninth-2, ninth-3, ninth-4, ninth-5 and ninth-6 upper overlay key patterns 61_1, 61_2, 61_3, 61_4, 61_5 and 61_6, respectively, about the sixth center point C6.

The eleventh upper overlay key sub-group 63a may be disposed to be rotated by 90 degrees in a clockwise direction with respect to the tenth upper overlay key sub-group 62a about the sixth center point C6.

The twelfth upper overlay key sub-group 64a may be disposed to be rotated by 90 degrees in a clockwise direction with respect to the eleventh upper overlay key sub-group 63a about the sixth center point C6.

The number of the upper overlay key patterns included in the upper overlay key sub-groups may not be limited

The pair of third overlay key groups 60a and 60b may be formed by an exposure process using a pair of third upper overlay mark groups UOM3a and UOM3b disposed at a center of the second reticle R2.

The pair of first lower overlay key structures LOK1a and LOK1b and the pair of first upper overlay key structures UOK1a and UOK1b may form a pair of first overlay key structures OKS1a and OKS1b, respectively. Particularly, the first lower overlay key structure LOK1a and the first upper overlay key structure UOK1a may form the first overlay key structure OKS1a, and the first lower overlay key structure LOK1b and the first upper overlay key structure UOK1b may form the first overlay key structure OKS1b.

Likewise, the pair of second lower overlay key structures LOK2a and LOK2b and the pair of second upper overlay key structures UOK2a and UOK2b may form a pair of second overlay key structures OKS2a and OKS2b, respectively. Particularly, the second lower overlay key structure LOK2a and the second upper overlay key structure UOK2a may form the second overlay key structure OKS2a, and the second lower overlay key structure LOK2b and the second upper overlay key structure UOK2b may form the second overlay key structure OKS2b.

A mold layer structure including the first insulation layers 310 and the fourth sacrificial layers 320 alternately and repeatedly stacked may undergo physical deformation when heat is applied due to a difference in coefficients of thermal expansion between the first insulation layer 310 and the fourth sacrificial layer 320. As a result, an overlay key penetrating through the mold layer structure may be pushed so that a mold stress overlay may be induced. The mold stress overlay may be calculated, as follows.

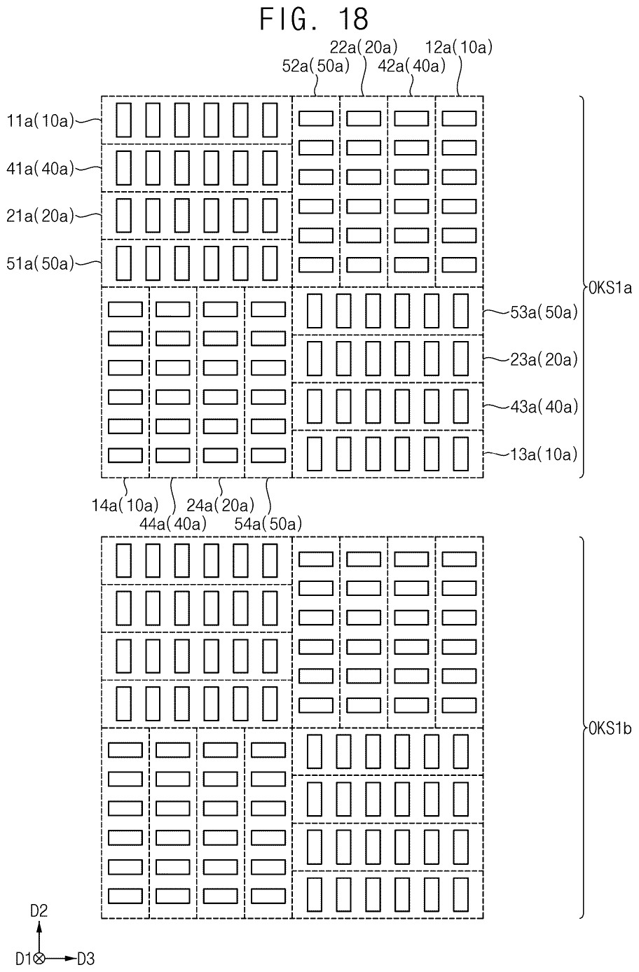

An A measured overlay may be obtained from the first center point C1 of the first lower overlay key group 10a of the first overlay key structure OKS1a and the fourth center of the first upper overlay key group 40a (refer to FIG. 18). A B measured overlay may be obtained from the first center point C1 of the first lower overlay key group 10b of the first overlay key structure OKS1b and the fourth center of the first upper overlay key group 40b.

The measured overlay may be assumed to be a sum of an actual overlay and a mold stress overlay caused by the mold stress.

$$A measured overlay = actual overlay + A mold stress overlay \qquad ( 1 )$$

$$B measured overlay = actual overlay + B mold stress overlay \qquad ( 2 )$$

The pair of first overlay key structures OKS1a and OKS1b are designed to be disposed at respective sides of the first center line CL1 that may penetrate through the center of the first lower mold layer structure and extend in the third direction D3, and thus, if it is assumed that the pair of first overlay key structures OKS1a and OKS1b are subject to mold stresses having the same magnitude and acting in opposite directions, a sum of the A mold stress overlay and the B mold stress overlay may be zero.

$$A mold stress overlay + B mold stress overlay = 0 \qquad ( 3 )$$

From equations (1) to (3), the actual overlay, the A mold stress overlay, and the B mold stress overlay may be obtained, as follows.

$$Actual overlay = 0.5 \times \{ ( A measured overlay ) + ( B measured overlay ) \} \qquad ( 4 )$$

$$A mold stress overlay = 0.5 \times \{ ( A measured overlay ) - ( B measured overlay ) \} \qquad ( 5 )$$

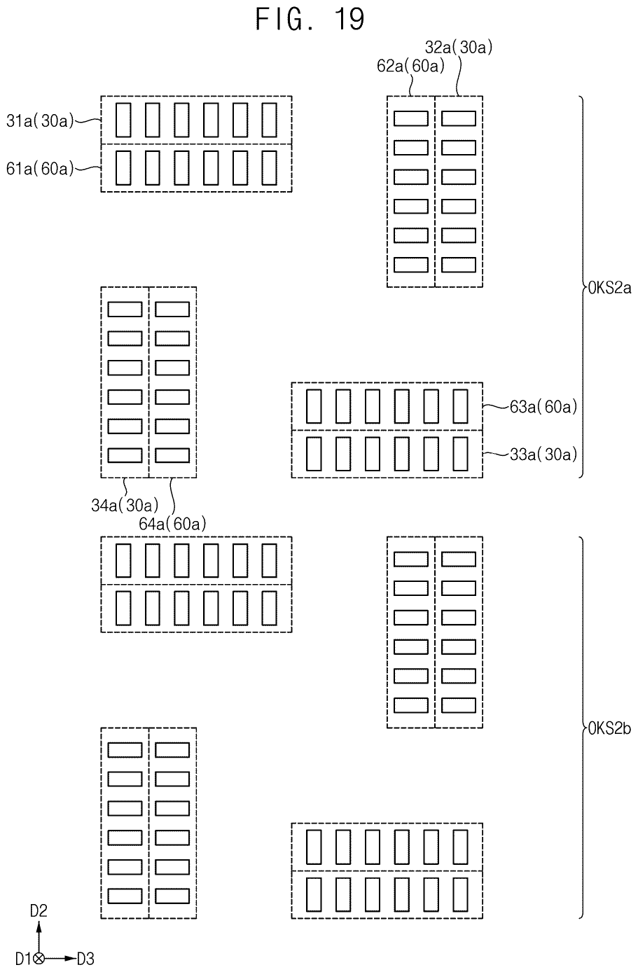

Through a method similar to the above-described method, an actual overlay and a mold stress overlay may be obtained based on the pair of second lower overlay key groups 20a and 20b and the pair of second upper overlay key groups 50a and 50b of the pair of first overlay key structures OKS1a and OKS1b (refer to FIG. 18), and the pair of third lower overlay key groups 30a and 30b and the pair of third upper overlay key groups 60a and 60b of the pair of second overlay key structures OKS2a and OKS2b (refer to FIG. 19).

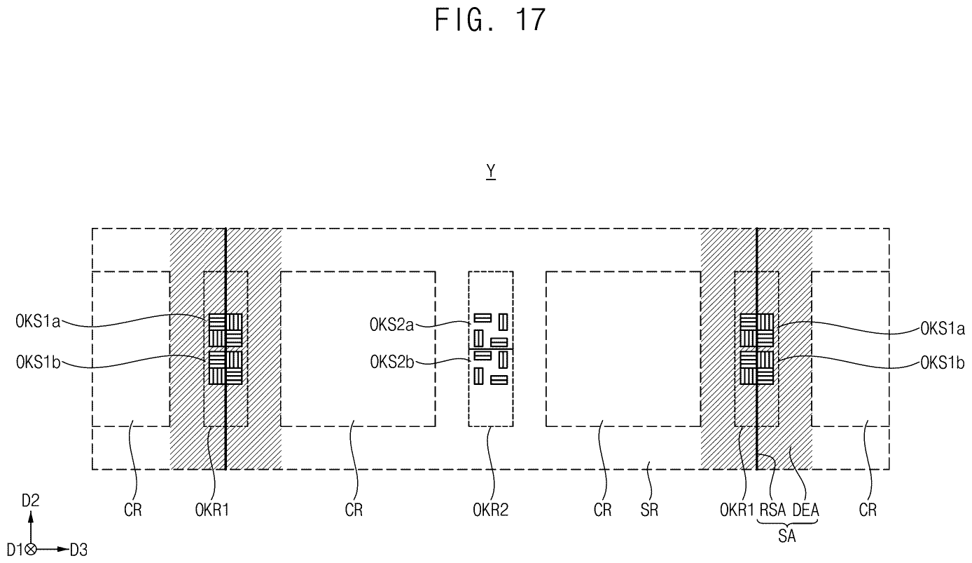

FIGS. 17 to 19 show that the pair of first lower overlay key structures LOK1a and LOK1b and the pair of first upper overlay key structures UOK1a and UOK1b, and the pair of second lower overlay key structures LOK2a and LOK2b and the pair of second upper overlay key structures UOK2a and UOK2b are ideally aligned so that no overlay error occurs.

In this case, the pair of first lower overlay key structures LOK1a and LOK1b and the pair of first upper overlay key structures UOK1a and UOK1b may overlap each other in the first direction D1. Likewise, the pair of second lower overlay key structures LOK2a and LOK2b and the pair of second upper overlay key structures UOK2a and UOK2b may not overlap each other in the first direction D1.

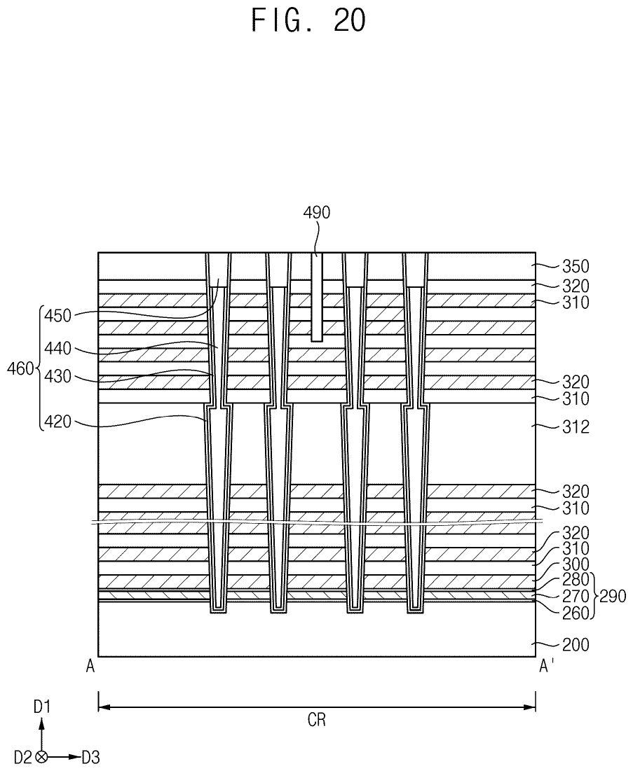

Referring to FIG. 20, for example, a dry etching process may be performed to form a channel hole extending through the first insulating interlayer 350 and the third upper mold layer structure and exposing an upper surface of the sacrificial filler 314.

The sacrificial filler 314 may be removed through the channel hole. Thus, the channel hole may be enlarged in the first direction D1, and the upper surface of the substrate 200 may be exposed.

In example embodiments, a plurality of channel holes may be formed to be spaced apart from each other in each of the second and third directions D2 and D3 to form a channel hole array.

A charge storage layer structure and a channel layer may be sequentially formed on a sidewall of the channel hole, the exposed upper surface of the substrate 200 and an upper surface of the first insulating interlayer 350, and a filling layer may be formed on the channel layer to fill the channel hole. The charge storage layer structure may include a first blocking layer, a charge storage layer and a tunnel insulation layer sequentially stacked.

A planarization process may be performed on the filling layer, the channel layer and the charge storage layer structure until the upper surface of the first insulating interlayer 350 is exposed to form a filling pattern 440, a channel 430 and a charge storage structure 420 in the channel hole. The charge storage structure 420 may include a first blocking pattern, a charge storage pattern and a tunnel insulation pattern sequentially stacked.

In example embodiments, the filling pattern 440 may have a shape of a pillar extending in the first direction D1, and each of the channel 430 and the charge storage structure 420 may have a shape of a cup.

As the channel holes are spaced apart from each other to form the channel hole array, the channels 430 that may be formed in the channel holes, respectively, may be formed to be spaced apart from each other to form a channel array.

Upper portions of the filling pattern 440 and the channel 430 may be removed to form a second recess, a capping layer may be formed on the filling pattern 440, the channel 430, the charge storage structure 420 and the first insulating interlayer 350 to fill the second recess, and a planarization process may be performed on the capping layer until the upper surface of the first insulating interlayer 350 is exposed to form a capping pattern 450 contacting an upper sidewall of the charge storage structure 420.

The charge storage structure 420, the channel 430 and the filling pattern 440 sequentially stacked from the sidewall and a bottom of the channel hole, and the capping pattern 450 may collectively form a memory channel structure 460.

The tunnel insulation pattern and the first blocking pattern may include an oxide, e.g., silicon oxide, the charge storage pattern may include a nitride, e.g., silicon nitride. The channel 430 may include, e.g., silicon. The filling pattern 440 may include an oxide, e.g., silicon oxide. The capping pattern 450 may include, e.g., polysilicon doped with n-type impurities, or a metal such as titanium, tantalum, etc.

The memory channel structure 460 may include a lower portion and an upper portion stacked in the first direction D1, and each of the lower and upper portions of the memory channel structure 460 may have a width decreasing from a top toward a bottom thereof. In example embodiments, an upper surface of the lower portion of the memory channel structure 460 may have an area greater than an area of a lower surface of the upper portion of the memory channel structure 460.

In example embodiments, the upper surface of the lower portion of the memory channel structure 460 may be substantially coplanar with the upper surfaces of the lower overlay key patterns included in the first and second lower overlay key structures LOK1a, LOK1b, LOK2a and LOK2b.

FIG. 20 shows that the memory channel structure 460 includes the lower and upper portions, that is, two portions stacked in the first direction D1, however, the inventive concept may not be limited thereto, and the memory channel structure 460 may include more than two portions stacked in the first direction D1. In this case, each of the portions of the memory channel structure 460 may have a width decreasing form a top toward a bottom thereof, and an upper surface of a relatively lower portion may have an area greater than an area of a lower surface of a relatively upper portion.

The first insulating interlayer 350, some of the first insulation layers 310 and some of the fourth sacrificial layers 320 may be etched to form a second opening extending in the second direction D2, and a first division pattern 490 may be formed in the second opening. The first division pattern 490 may include an oxide, e.g., silicon oxide.

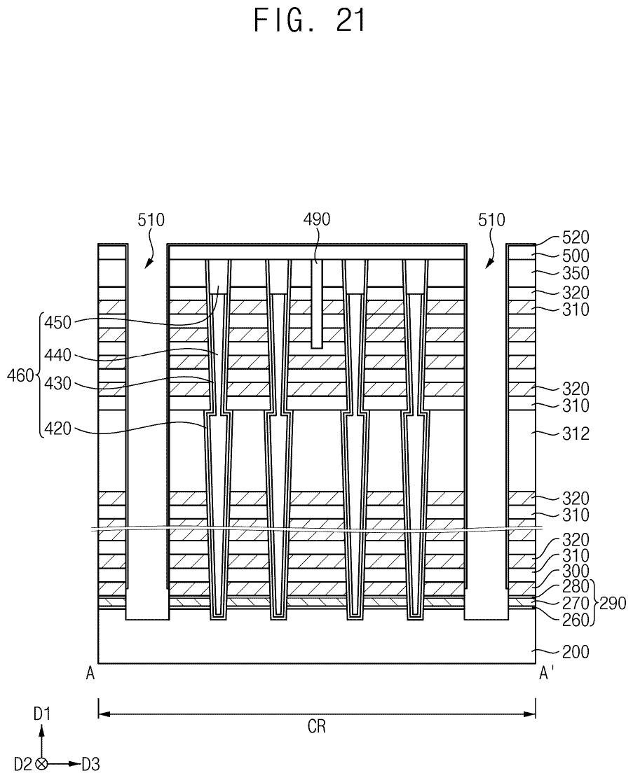

Referring to FIG. 21, a second insulating interlayer 500 may be formed on the first insulating interlayer 350 and the memory channel structure 460, and for example, a dry etching process may be performed to form a third opening 510 extending through the first and second insulating interlayers 300 and 500 and the third lower and upper mold layer structures.

In example embodiments, the dry etching process may be performed until the third opening 510 exposes an upper surface of the support layer 300 or the support pattern, and the third opening 510 may extend through an upper portion of the support layer 300 or the support pattern. As the third opening 510 is formed, the first insulation layer 310, the second insulation layer 312 and the fourth sacrificial layer 320 included in the third lower and upper mold layer structures may be exposed.

In example embodiments, the third opening 510 may extend in the second direction D2, and a plurality of third openings 510 may be formed to be spaced apart from each other in the third direction D3. As the third opening 510 is formed, the first insulation layer 310 may be divided into first insulation patterns 315 extending in the second direction D2, the second insulation layer 312 may be divided into second insulation patterns 319 extending in the second direction D2, and that fourth sacrificial layer 320 may be divided into fourth sacrificial patterns 325.

A spacer layer may be formed on a sidewall of the third opening 510, the exposed upper surfaces of the support layer 300 and the support pattern, and an upper surface of the second insulating interlayer 500, and may be anisotropically etched to form a spacer 520 so that the upper surfaces of the support layer 300 and the support pattern may also be exposed. In example embodiments, the spacer 520 may include undoped polysilicon or undoped amorphous silicon.

Portions of the support layer 300 and the support pattern not covered by the spacer 520 and a portion of the sacrificial layer structure 290 thereunder may be removed so that the third opening 510 may be enlarged downwardly. Accordingly, the third opening 510 may expose the upper surface of the substrate 200, and may also extend through an upper portion of the substrate 200.

When the sacrificial layer structure 290 is removed, the sidewall of the third opening 510 may be covered by the spacer 520, and the spacer 520 may include a material difficult from that of the sacrificial layer structure 290, so that the first insulation pattern 315 and the fourth sacrificial pattern 325 may not be removed.

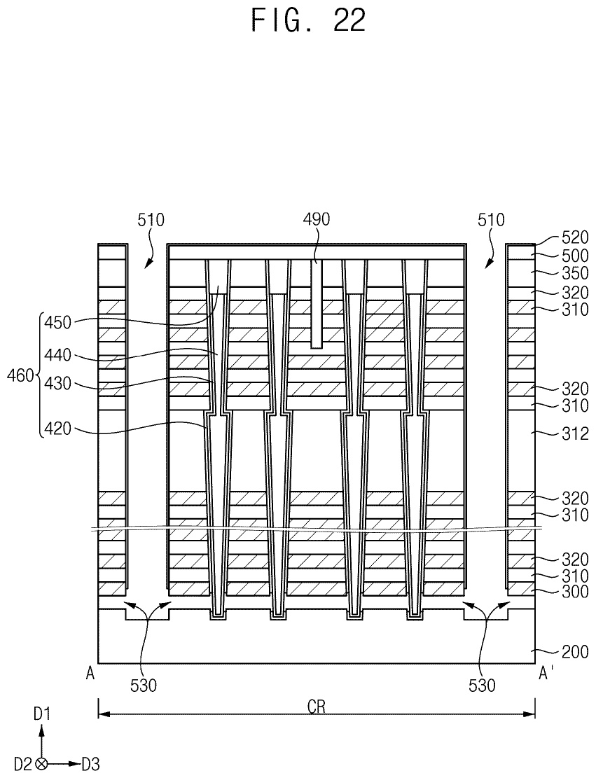

Referring to FIG. 22, the sacrificial layer structure 290 exposed by the third opening 510 may be removed to form a first gap 530 exposing a lower outer sidewall of the charge storage structure 420, and a portion of the charge storage structure 420 exposed by the first gap 530 may also be removed to expose a lower outer sidewall of the channel 430.

The sacrificial layer structure 290 and the charge storage structure 420 may be removed by a wet etching selectivity using, e.g., hydrofluoric acid (HF) and/or phosphoric acid (H₃PO₄). When the first gap 530 is formed, the support layer 300, the support pattern, the channel 430 and the filling pattern 440 may not be removed, but support the third lower and upper mold layer structure.

As the first gap 530 is formed, the charge storage structure 420 may be divided into an upper portion extending through the third mold layer structure to cover most portion of the channel 430, and a lower portion covering a lower surface of the channel 430 on the substrate 200.

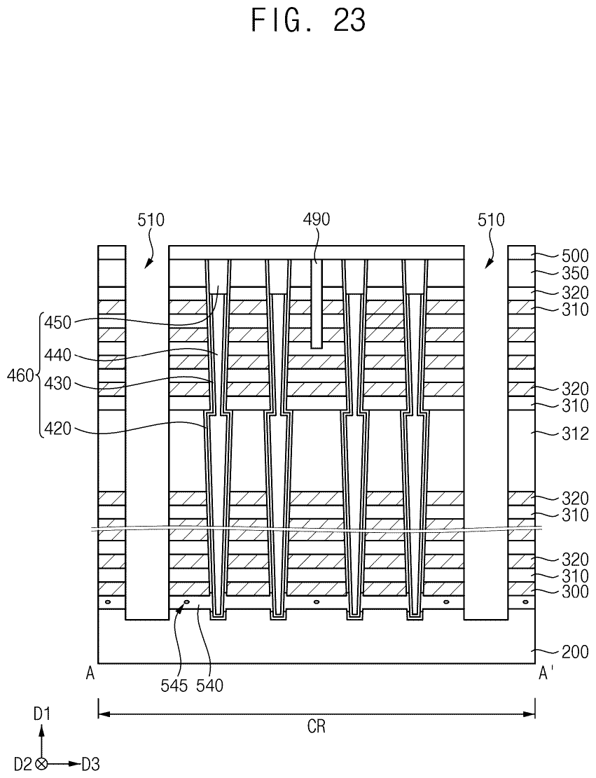

Referring to FIG. 23, after removing the spacer 520, a channel connection pattern 540 may be formed in the first gap 530.

The channel connection pattern 540 may be formed by forming a channel connection layer to fill the third opening 510 and the first gap 530 on the substrate 200 and the second insulating interlayer 500, and performing an etch back process on the channel connection layer. The channel connection layer may include, e.g., polysilicon doped with n-type impurities. As the channel connection pattern 540 is formed, ones of the channels 430 disposed between neighboring ones of the third openings 510 may be connected to each other to form a channel block.

In some embodiments, air gap 545 may be formed in the channel connection pattern 540.

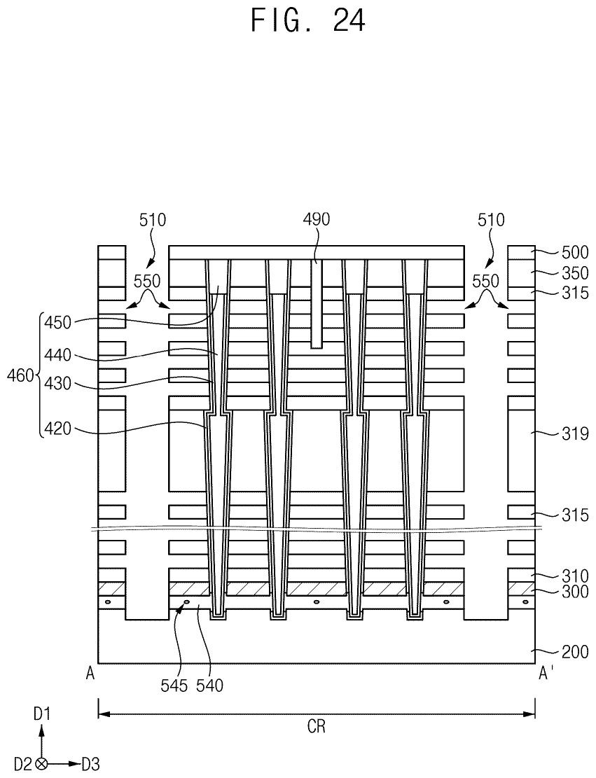

Referring to FIG. 24, for example, n-type impurities may be doped into the upper portion exposed by the third opening 510 to form an impurity region.

The fourth sacrificial pattern 325 may be removed to form a second gap 550 exposing an outer sidewall of the charge storage structure 420. The fourth sacrificial pattern 325 may be removed by a wet etching selectivity using, e.g., hydrofluoric acid (HF) and/or phosphoric acid (H₃PO₄).

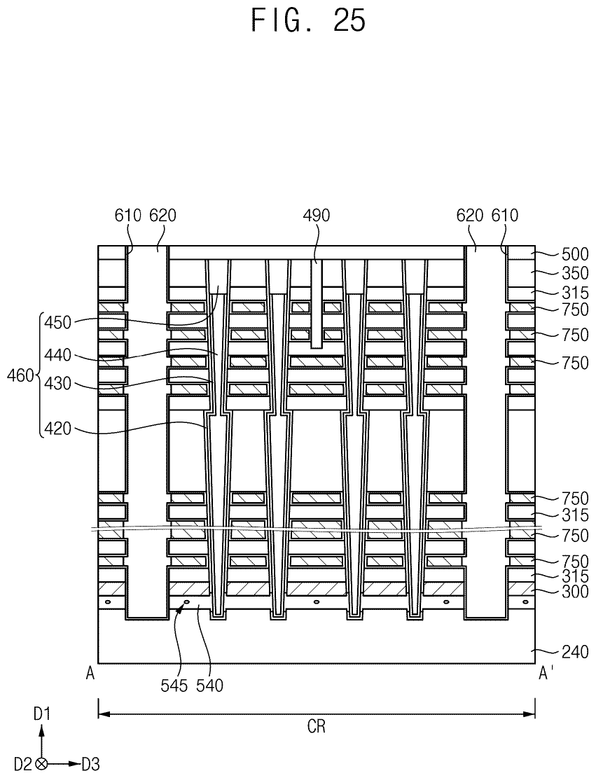

Referring to FIG. 25, a second blocking layer may be formed on the outer sidewall of the charge storage structure 420, an inner wall of the second gap 550, a surface of the first insulation pattern 315, the sidewalls of the support layer 300 and the support pattern, a sidewall of the channel connection pattern 540, the upper surface of the substrate 200 and the upper surface of the second insulating interlayer 500, and a gate electrode layer may be formed on the second blocking layer to fill the second gap 550 and the third opening 510. The gate electrode layer may include a metal having a low resistance, e.g., tungsten, titanium, tantalum, platinum, etc., and the gate barrier layer may include a metal nitride, e.g., titanium nitride, tantalum nitride, etc.

The gate electrode layer may be partially removed to form a gate electrode 750 in the second gap. In example embodiments, the gate electrode layer may be removed by a wet etching process.

In example embodiments, the gate electrode 750 may extend in the second direction D2, and a plurality of gate electrodes 750 may be spaced apart from each other in the first direction D1 to form a gate electrode structure. Additionally, a plurality of gate electrode structures may be spaced apart from each other in the third direction D3.

The gate electrodes 750 sequentially stacked in the first direction D1 may serve as a ground selection line (GSL), a word line and a string selection line (SSL) according to positions thereof. In an example embodiment, a lowermost one of the gate electrodes 750 may serve as the GSL, an uppermost one and a second one directly under the uppermost one of the gate electrodes 750 may serve as the SSL, and other ones of the gate electrodes 750 between the GSL and the SSL may serve as the word lines, respectively.

However, some of the gate electrodes 750 under the GSL and/or over the SSL may serve as a gate induced drain leakage (GIDL) gate electrode that may perform body erase operation using GIDL phenomenon, and others of the gate electrodes 750 serving as the word lines may be dummy word lines.

A second division layer may be formed on the second blocking layer to fill the third opening 510, and a planarization process may be performed on the second division layer and the second blocking layer until the upper surface of the second insulating interlayer 500 is exposed. Thus, the second blocking layer may be transformed into a second blocking pattern 610, and the second division layer may be divided into a plurality of second division patterns 620 each of which may fill the third opening 510 and extend in the second direction D2. The second blocking pattern 620 may include a metal oxide, e.g., aluminum oxide, hafnium oxide, etc., and the second division pattern 390 may include an oxide, e.g., silicon oxide.

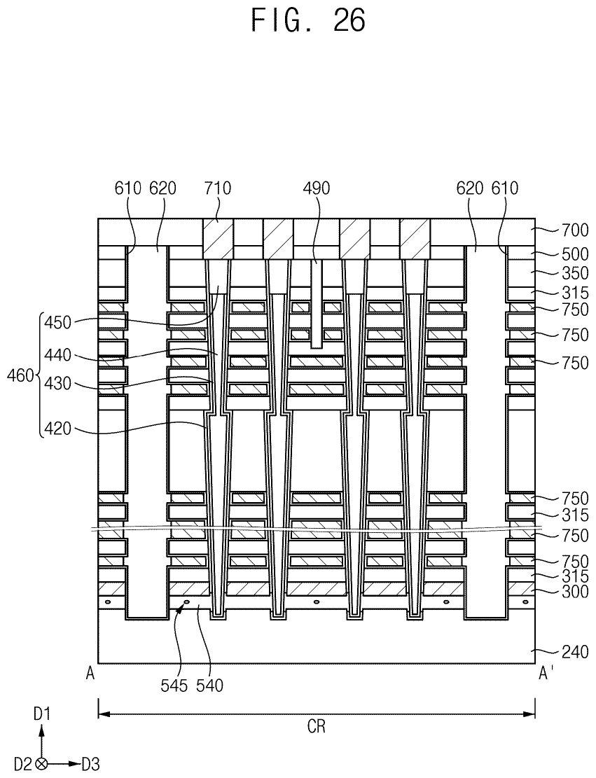

Referring to FIG. 26, a third insulating interlayer 700 may be formed on the second insulating interlayer 500, the second division pattern 620 and the second blocking pattern 610, and a contact plug 710 may be formed through the second and third insulating interlayers 500 and 700 to contact an upper surface of the memory channel structure 460.

A bit line may be formed on the third insulating interlayer 700 to contact the contact plug 710. In example embodiments, the bit line may extend in the third direction D3, and a plurality of bit lines may be spaced apart from each other in the second direction D2.

An upper contact plug contacting the gate electrode 750 and an upper wiring for applying electric signal to the gate electrode 750 may be further formed to complete the fabrication of the semiconductor device.

In the drawings, a vertical NAND flash memory device is formed on the chip region CR of the substrate 200, however, the inventive concept may not be limited thereto. For example, a non-volatile memory device such as a PRAM device or a RRAM device, or a volatile device such as a DRAM device or an SRAM device may be formed on the chip region CR of the substrate 200.

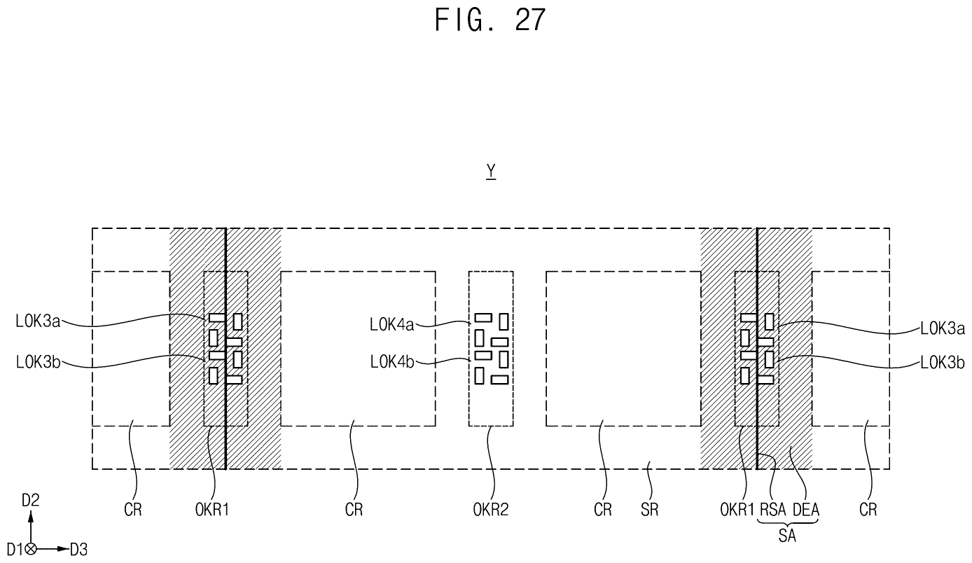

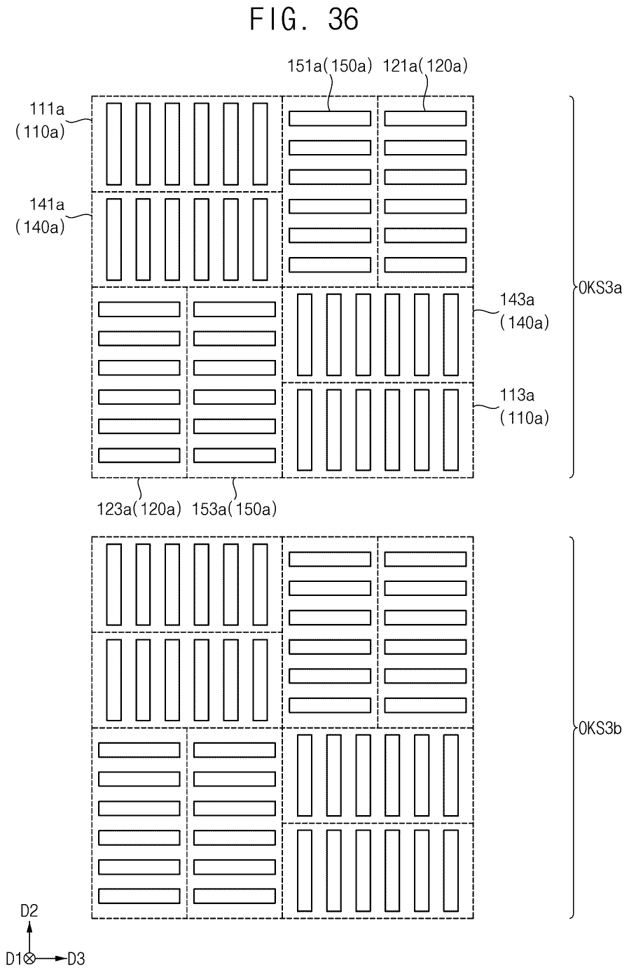

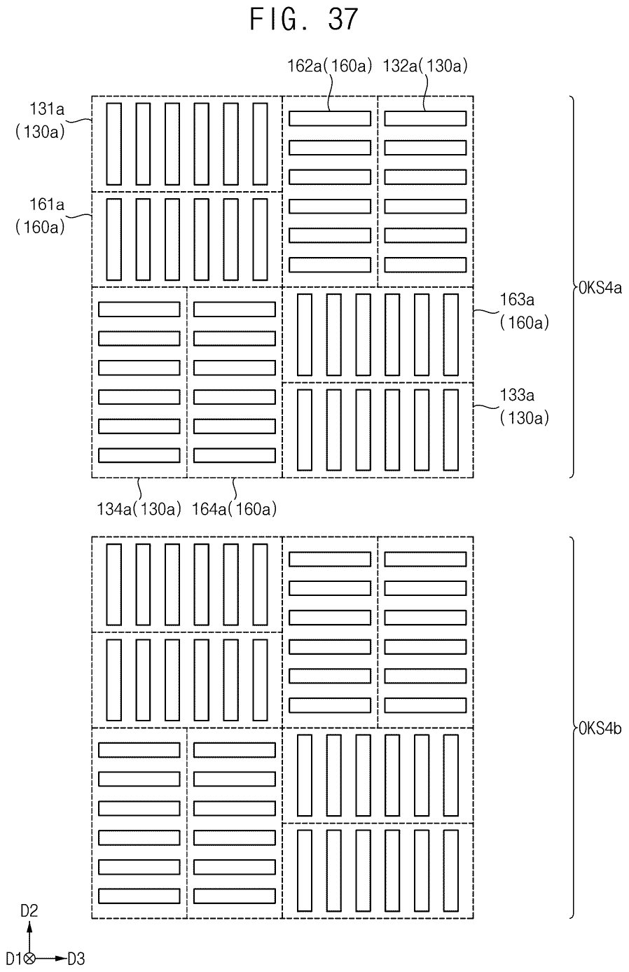

FIGS. 27 to 37 are enlarged plan views and cross-sectional views illustrating a method of manufacturing a semiconductor device in accordance with example embodiments.

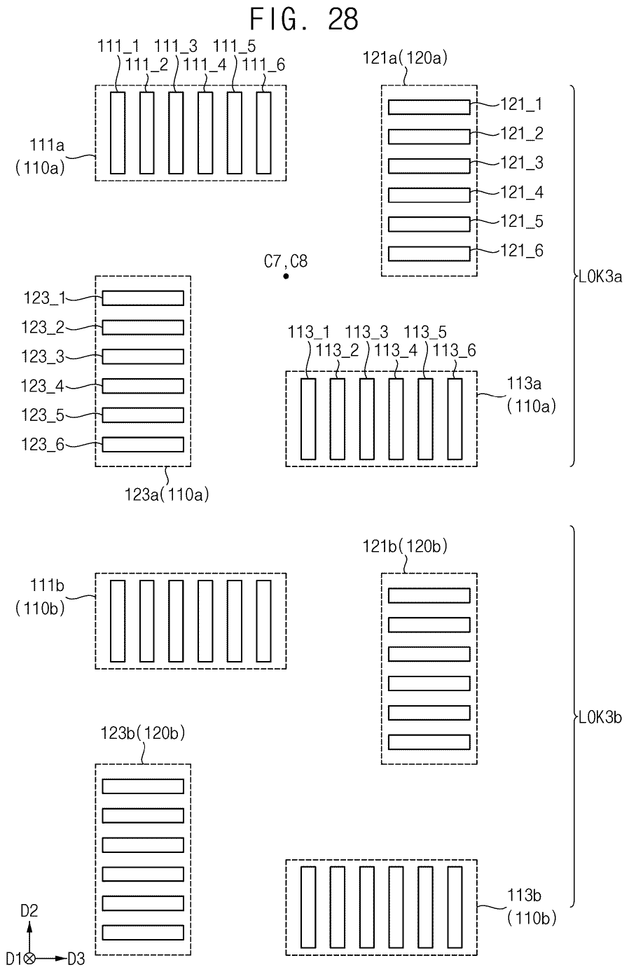

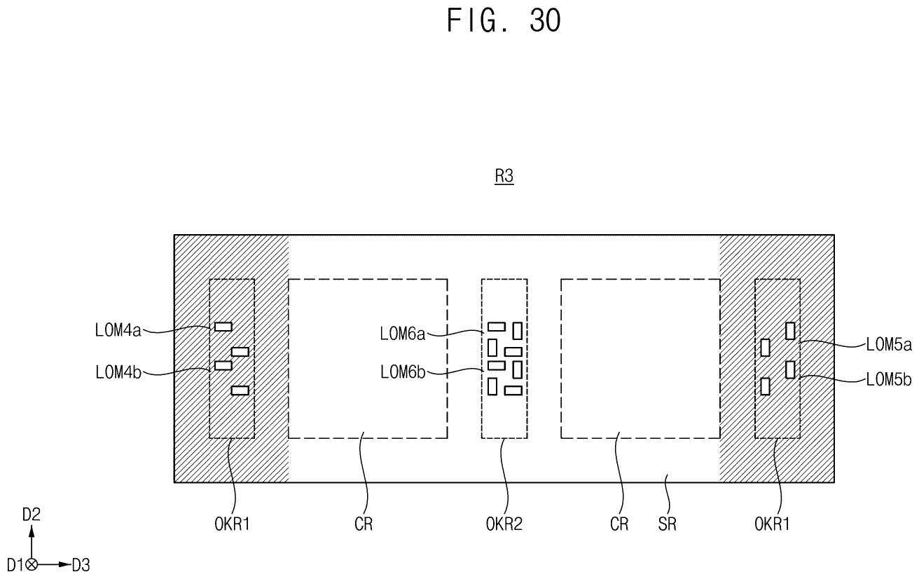

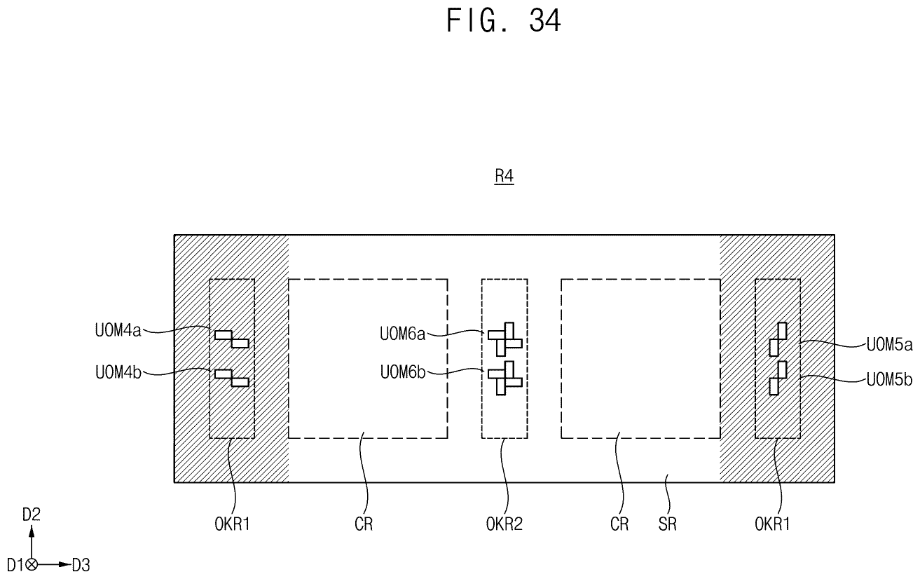

Particularly, FIGS. 27, 31 and 35 are enlarged plan views of regions Y of corresponding plan views, respectively. FIGS. 28-29, 32-33 and 36-37 are enlarged plan views illustrating layouts of overlay key structures, and FIGS. 30 and 34 are enlarged plan views illustrating a portion of a reticle.

This method may include processes substantially the same as or similar to those illustrated with reference to FIGS. 1 to 26, and thus repeated explanations thereof are omitted herein.

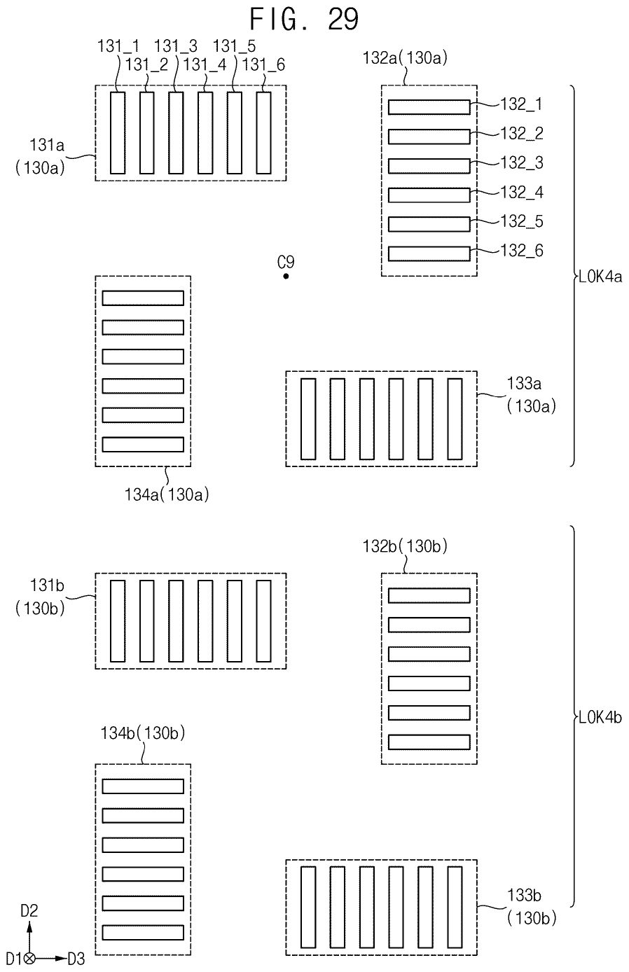

Referring to FIGS. 29 to 30, processes substantially the same as or similar to those illustrated with reference to FIGS. 1 to 9 may be performed. However, unlike those of FIGS. 5 to 9, a pair of third lower overlay key structures LOK3a and LOK3b and a pair of fourth lower overlay key structures LOK4a and LOK4b may be formed on the second overlay key region R2, instead of the pair of first lower overlay key structures LOK1a and LOK1b and the pair of second lower overlay key structures LOK2a and LOK2b.

That is, the pair of third lower overlay key structures LOK3a and LOK3b may be formed on the first overlay key region OKR1, and the pair of fourth lower overlay key structures LOK4a and LOK4b may be formed on the second overlay key region OKR2.

The pair of third lower overlay key structures LOK3a and LOK3b may be disposed at opposite sides, respectively, of the first center line CL1.

Components of the pair of third lower overlay key structures LOK3a and LOK3b, respectively, which may include e.g., lower overlay key patterns, may be arranged by the same layout. Hereinafter, only the third lower overlay key structure LOK3a is described.

The third lower overlay key structure LOK3a may include fourth and fifth lower overlay key groups 110a and 120a (refer to FIG. 28).

The fourth lower overlay key group 110a may include thirteenth and fourteenth lower overlay key sub-groups 111a and 113a. The thirteenth and fourteenth lower overlay key sub-groups 111a and 113a may be disposed to be rotated 180 degrees in a clockwise direction about a seventh center point C7. That is, the fourth lower overlay key group 110a may have 180-degree rotational symmetry.

In example embodiments, the thirteenth lower overlay key sub-group 111a may include thirteenth-1, thirteenth-2, thirteenth-3, thirteenth-4, thirteenth-5 and thirteenth-6 lower overlay key patterns 111_1, 111_2, 111_3, 111_4, 111_5 and 111_6. Each of the thirteenth-1, thirteenth-2, thirteenth-3, thirteenth-4, thirteenth-5 and thirteenth-6 lower overlay key patterns 111_1, 111_2, 111_3, 111_4, 111_5 and 111_6 may extend in the second direction D2, and the thirteenth-1, thirteenth-2, thirteenth-3, thirteenth-4, thirteenth-5 and thirteenth-6 lower overlay key patterns 111_1, 111_2, 111_3, 111_4, 111_5 and 111_6 may be spaced apart from each other in the third direction D3.

In example embodiments, the fourteenth lower overlay key sub-group 113a may include fourteenth-1, fourteenth-2, fourteenth-3, fourteenth-4, fourteenth-5 and fourteenth-6 lower overlay key patterns 113_1, 113_2, 113_3, 113_4, 113_5 and 113_6. The fourteenth lower overlay key sub-group 113a may be disposed to be rotated by 180 degrees in a clockwise direction with respect to the thirteenth lower overlay key sub-group 111a about the seventh center point C7. For example, referring to FIG. 28, the fourteenth-1, fourteenth-2, fourteenth-3, fourteenth-4, fourteenth-5 and fourteenth-6 lower overlay key patterns 113_1, 113_2, 113_3, 113_4, 113_5 and 113_6 may be disposed to be rotated by 180 degrees in a clockwise direction with respect to the thirteenth-1, thirteenth-2, thirteenth-3, thirteenth-4, thirteenth-5 and thirteenth-6 lower overlay key patterns 111_1, 111_2, 111_3, 111_4, 111_5 and 111_6, respectively, about the seventh center point C7.

The fifth lower overlay key group 120a may include fifteenth and sixteenth lower overlay key sub-groups 121a and 123a. The fifteenth and sixteenth lower overlay key sub-groups 121a and 123a may be disposed to be rotated by 180 degrees in a clockwise direction with respect to each other about an eighth center point C8. That is, the fifth lower overlay key group 120a may have 180-degree rotational symmetry. The fifteenth and sixteenth lower overlay key sub-groups 121a and 123a of the fifth lower overlay key group 120a may have an arrangement substantially identical to that obtained by rotating the thirteenth and fourteenth lower overlay key sub-groups 111a and 113a of the fourth lower overlay key group 110a 90 degrees in a clockwise direction.

In example embodiments, the fifteenth lower overlay key sub-group 121a may include fifteenth-1, fifteenth-2, fifteenth-3, fifteenth-4, fifteenth-5 and fifteenth-6 lower overlay key patterns 121_1, 121_2, 121_3, 121_4, 121_5 and 121_6. Each of the fifteenth-1, fifteenth-2, fifteenth-3, fifteenth-4, fifteenth-5 and fifteenth-6 lower overlay key patterns 121_1, 121_2, 121_3, 121_4, 121_5 and 121_6 may extend in the third direction D3, and the fifteenth-1, fifteenth-2, fifteenth-3, fifteenth-4, fifteenth-5 and fifteenth-6 lower overlay key patterns 121_1, 121_2, 121_3, 121_4, 121_5 and 121_6 may be spaced apart from each other in the second direction D2.

In example embodiments, the sixteenth lower overlay key sub-group 123a may include sixteenth-1, sixteenth-2, sixteenth-3, sixteenth-4, sixteenth-5 and sixteenth-6 lower overlay key patterns 123_1, 123_2, 123_3, 123_4, 123_5 and 123_6, and may be disposed to be rotated by 180 degrees in a clockwise direction with respect to the fifteenth lower overlay key sub-group 121a about the eighth center point C8. For example, referring to FIG. 28, the sixteenth-1, sixteenth-2, sixteenth-3, sixteenth-4, sixteenth-5 and sixteenth-6 lower overlay key patterns 123_1, 123_2, 123_3, 123_4, 123_5 and 123_6 of the sixteenth lower overlay key sub-group 123a may be disposed to be rotated by 180 degrees in a clockwise direction with respect to the fifteenth-1, fifteenth-2, fifteenth-3, fifteenth-4, fifteenth-5 and fifteenth-6 lower overlay key patterns 121_1, 121_2, 121_3, 121_4, 121_5 and 121_6 of the fifteenth lower overlay key sub-group 121a.

In the drawings, a case in which the fourth lower overlay key group 110a and the fifth lower overlay key group 120a are ideally aligned with each other such that the seventh center point C7 coincides with the eighth center point C8 is illustrated.

However, for example, the fourth lower overlay key group 110a may be formed by an exposure process using a fourth lower mark group LOM4a disposed at a left edge of a third reticle R3, and the fifth lower overlay key group 120a may be formed by an exposure process using a fifth lower mark group LOM5a disposed at a right edge of the third reticle R3. That is, the fourth and fifth overlay key groups 110a and 120a may be formed by independent exposure processes, and thus, in some cases, the seventh center point C7 and the eighth center point C8 may not coincide with each other, but may be offset to each other.

As illustrated above, the layouts of the lower overlay key patterns included in the pair of third lower overlay key structures LOK3a and LOK3b, respectively, may be substantially the same as each other. Particularly, layouts of the lower overlay key patterns included in fourth and fifth lower overlay key groups 110b and 120b of the third lower overlay key structure LOK3b may be substantially the same as layouts of the lower overlay key patterns included in fourth and fifth lower overlay key groups 110a and 120a of the third lower overlay key structure LOK3a.

A pair of fourth lower overlay key groups 110a and 110b may be formed by an exposure process using a pair of fourth lower overlay mark groups LOM4a and LOM4b disposed at a left edge of the third reticle R3, and a pair of fifth lower overlay key groups 120a and 120b may be formed by an exposure process using a pair of fifth lower overlay mark groups LOM5a and LOM5b disposed at a right edge of the third reticle R3.

The pair of fourth lower overlay key structures LOK4a and LOK4b may be disposed at opposite sides, respectively, of the second center line CL2.

Components of the pair of fourth lower overlay key structures LOK4a and LOK4b, respectively, which may include e.g., lower overlay key patterns, may be arranged by the same layout. Hereinafter, only the fourth lower overlay key structure LOK4a is described.

The fourth lower overlay key structure LOK4a may include a sixth lower overlay key group 130a, and the sixth lower overlay key group 130a may include seventeenth, eighteenth, nineteenth and twentieth lower overlay key sub-groups 131a, 132a, 133a and 134a. The seventeenth to twentieth lower overlay key sub-groups 131a, 132a, 133a and 134a may be disposed to be rotated by 90 degrees in a clockwise direction about a ninth center point C9. That is, the fourth lower overlay key group 130a may have 90-degree rotational symmetry.

In example embodiments, the seventeenth lower overlay key sub-group 131a may include seventeenth-1, seventeenth-2, seventeenth-3, seventeenth-4, seventeenth-5 and seventeenth-6 lower overlay key patterns 131_1, 131_2, 131_3, 131_4, 131_5 and 131_6. Each of the seventeenth-1, seventeenth-2, seventeenth-3, seventeenth-4, seventeenth-5 and seventeenth-6 lower overlay key patterns 131_1, 131_2, 131_3, 131_4, 131_5 and 131_6 may extend in the second direction D2, and the seventeenth-1, seventeenth-2, seventeenth-3, seventeenth-4, seventeenth-5 and seventeenth-6 lower overlay key patterns 131_1, 131_2, 131_3, 131_4, 131_5 and 131_6 may be spaced apart from each other in the third direction D3.

In example embodiments, the eighteenth lower overlay key sub-group 132a may include eighteenth-1, eighteenth-2, eighteenth-3, eighteenth-4, eighteenth-5 and eighteenth-6 lower overlay key patterns 132_1, 132_2, 132_3, 132_4, 132_5 and 132_6. The eighteenth lower overlay key sub-group 132a may be disposed to be rotated by 90 degrees in a clockwise direction with respect to the seventeenth lower overlay key sub-group 131a about the ninth center point C9. For example, referring to FIG. 29, the eighteenth-1, eighteenth-2, eighteenth-3, eighteenth-4, eighteenth-5 and eighteenth-6 lower overlay key patterns 132_1, 132_2, 132_3, 132_4, 132_5 and 132_6 of the eighteenth lower overlay key sub-group 132a may be disposed to be rotated by 90 degrees in a clockwise direction with respect to the seventeenth-1, seventeenth-2, seventeenth-3, seventeenth-4, seventeenth-5 and seventeenth-6 lower overlay key patterns 131_1, 131_2, 131_3, 131_4, 131_5 and 131_6, respectively, of the seventeenth lower overlay key sub-group 131a, about the ninth center point C9.

The nineteenth lower overlay key sub-group 133a may be disposed to be rotated by 90 degrees in a clockwise direction with respect to the eighteenth lower overlay key sub-group 132a about the ninth center point C9.

The twentieth lower overlay key sub-group 134a may be disposed to be rotated by 90 degrees in a clockwise direction with respect to the nineteenth lower overlay key sub-group 133a about the ninth center point C9.

As illustrated above, the layouts of the lower overlay key patterns included in the pair of fourth lower overlay key structures LOK4a and LOK4b, respectively, may be substantially the same as each other. Particularly, layouts of the lower overlay key patterns included in sixth lower overlay key group 130b of the fourth lower overlay key structure LOK4b may be substantially the same as layouts of the lower overlay key patterns included in sixth lower overlay key group 130a of the fourth lower overlay key structure LOK4a.

A pair of sixth lower overlay key groups 130a and 130b may be formed by an exposure process using a pair of sixth lower overlay mark groups LOM6a and LOM6b disposed at a center of a fourth reticle R4.

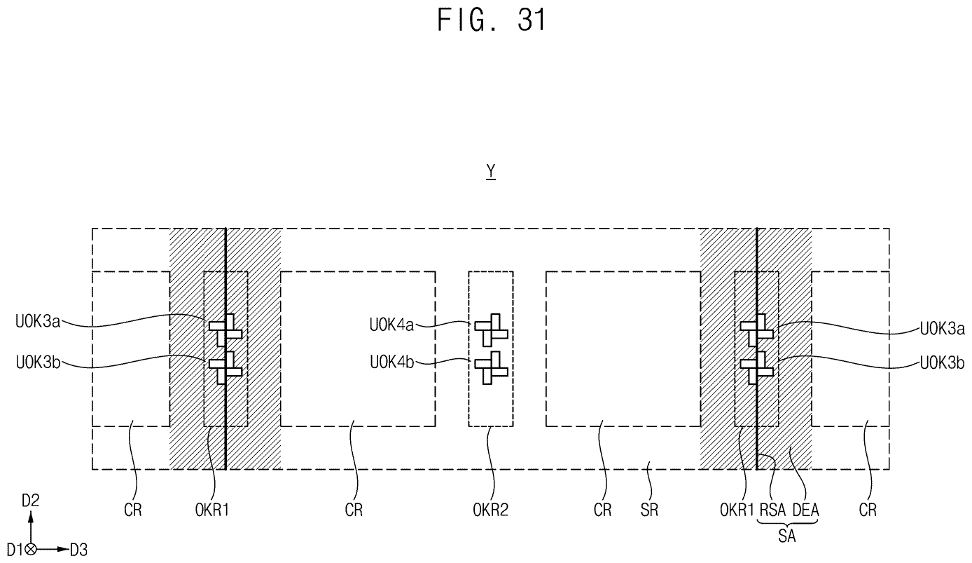

Referring to FIGS. 31 to 34, processes substantially the same as or similar to those illustrated with reference to FIGS. 10 to 16 may be performed.

However, unlike those of FIGS. 12 to 16, a pair of third upper overlay key structures UOK3a and UOK3b, and a pair of fourth upper overlay key structures UOK4a and UOK4b may be formed, instead of the pair of first upper overlay key structures UOK1a and UOK1b, and the pair of second upper overlay key structures UOK2a and UOK2b.

That is, the third upper overlay key structures UOK3a and UOK3b may be formed on the first overlay key region OKR1 of the substrate 200, and the pair of fourth upper overlay key structures UOK4a and UOK4b may be formed on the second overlay key region OKR2 of the substrate 200.

The pair of third upper overlay key structures UOK3a and UOK3b may be disposed at opposite sides, respectively, of the first center line CL1.

Components of the pair of third upper overlay key structures UOK3a and UOK3b, respectively, may be arranged by the same layout. Hereinafter, only the third upper overlay key structure UOK3a is described.

The third upper overlay key structure UOK3a may include fourth and fifth upper overlay key groups 140a and 150a.

The fourth upper overlay key group 140a may include thirteenth and fourteenth upper overlay key sub-groups 141a, and 143a. The thirteenth and fourteenth upper overlay key sub-groups 141a and 143a may be disposed to be rotated by 180 degrees in a clockwise direction about a tenth center point C10. That is, the fourth upper overlay key group 140a may have 180-degree rotational symmetry.

In example embodiments, the thirteenth upper overlay key sub-group 141a may include thirteenth-1, thirteenth-2, thirteenth-3, thirteenth-4, thirteenth-5 and thirteenth-6 upper overlay key patterns 141_1, 141_2, 141_3, 141_4, 141_5 and 141_6. Each of the thirteenth-1, thirteenth-2, thirteenth-3, thirteenth-4, thirteenth-5 and thirteenth-6 upper overlay key patterns 141_1, 141_2, 141_3, 141_4, 141_5 and 141_6 may extend in the second direction D2, and the thirteenth-1, thirteenth-2, thirteenth-3, thirteenth-4, thirteenth-5 and thirteenth-6 upper overlay key patterns 141_1, 141_2, 141_3, 141_4, 141_5 and 141_6 may be spaced apart from each other in the third direction D3.

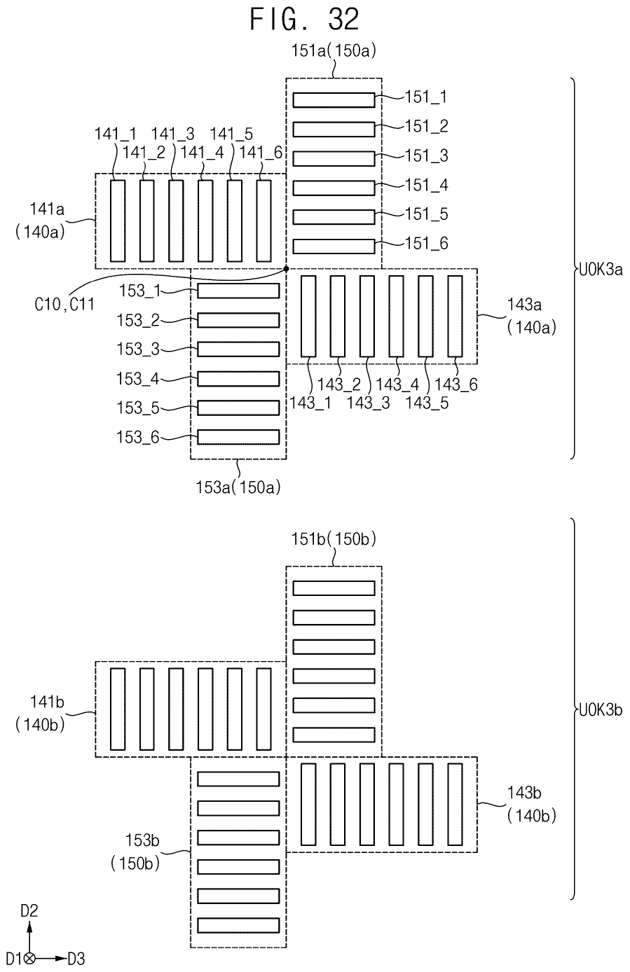

In example embodiments, the fourteenth upper overlay key sub-group 143a may include fourteenth-1, fourteenth-2, fourteenth-3, fourteenth-4, fourteenth-5 and fourteenth-6 upper overlay key patterns 143_1, 143_2, 143_3, 143_4, 143_5 and 143_6. The fourteenth upper overlay key sub-group 143a may be disposed to be rotated by 180 degrees in a clockwise direction with respect to the thirteenth upper overlay key sub-group 141a about the tenth center point C10. For example, referring to FIG. 32, the fourteenth-1, fourteenth-2, fourteenth-3, fourteenth-4, fourteenth-5 and fourteenth-6 upper overlay key patterns 143_1, 143_2, 143_3, 143_4, 143_5 and 143_6 of the fourteenth upper overlay key sub-group 143a may be disposed to be rotated by 180 degrees in a clockwise direction with respect to the thirteenth-1, thirteenth-2, thirteenth-3, thirteenth-4, thirteenth-5 and thirteenth-6 upper overlay key patterns 141_1, 141_2, 141_3, 141_4, 141_5 and 141_6, respectively, of the thirteenth upper overlay key sub-group 141a about the tenth center point C10.

The fifth upper overlay key group 150a may include fifteenth and sixteenth upper overlay key sub-groups 151a, and 153a. The fifteenth and sixteenth upper overlay key sub-groups 151a and 153a may be disposed to be rotated by 180 degrees in a clockwise direction about an eleventh center point C11. That is, the fifteenth upper overlay key group 150a may have 180-degree rotational symmetry. The fifteenth and sixteenth upper overlay key sub-groups 151a and 153a of the fifth upper overlay key group 150a may have an arrangement substantially identical to that obtained by rotating the thirteenth and fourteenth upper overlay key sub-groups 151a and 153a of the fourth upper overlay key group 140a 90 degrees in a clockwise direction.

In example embodiments, the fifteenth upper overlay key sub-group 151a may include fifteenth-1, fifteenth-2, fifteenth-3, fifteenth-4, fifteenth-5 and fifteenth-6 upper overlay key patterns 151_1, 151_2, 151_3, 151_4, 151_5 and 151_6. Each of the fifteenth-1, fifteenth-2, fifteenth-3, fifteenth-4, fifteenth-5 and fifteenth-6 upper overlay key patterns 151_1, 151_2, 151_3, 151_4, 151_5 and 151_6 may extend in the third direction D3, and the fifteenth-1, fifteenth-2, fifteenth-3, fifteenth-4, fifteenth-5 and fifteenth-6 upper overlay key patterns 151_1, 151_2, 151_3, 151_4, 151_5 and 151_6 may be spaced apart from each other in the second direction D2.

In example embodiments, the sixteenth upper overlay key sub-group 153a may include sixteenth-1, sixteenth-2, sixteenth-3, sixteenth-4, sixteenth-5 and sixteenth-6 upper overlay key patterns 153_1, 153_2, 153_3, 153_4, 153_5 and 153_6. The sixteenth upper overlay key sub-group 153a may be disposed to be rotated by 180 degrees in a clockwise direction with respect to the fifteenth upper overlay key sub-group 151a about the eleventh center point C11. For example, referring to FIG. 32, the sixteenth-1, sixteenth-2, sixteenth-3, sixteenth-4, sixteenth-5 and sixteenth-6 upper overlay key patterns 153_1, 153_2, 153_3, 153_4, 153_5 and 153_6 of the sixteenth upper overlay key sub-group 153a may be disposed to be rotated by 180 degrees in a clockwise direction with respect to the fifteenth-1, fifteenth-2, fifteenth-3, fifteenth-4, fifteenth-5 and fifteenth-6 upper overlay key patterns 151_1, 151_2, 151_3, 151_4, 151_5 and 151_6, respectively, of the fifteenth upper overlay key sub-group 151a about the eleventh center point C11.

In the drawing, the fourth upper overlay key group 140a and the fifth upper overlay key group 150a are ideally aligned with each other such that the tenth center point C10 coincides with the eleventh center point C11 is illustrated.

However, for example, the fourth upper overlay key group 140a may be formed by an exposure process using a fourth upper mark group UOM4a disposed at a left edge of a fourth reticle R4, and the fifth upper overlay key group 150a may be formed by an exposure process using a fifth upper lower mark group UOM5a disposed at a right edge of the fourth reticle R4. That is, the fourth and fifth upper overlay key groups 140a and 150a may be formed by independent exposure processes, and thus, in some cases, the tenth center point C10 and the eleventh center point C11 may not coincide with each other, but may be offset to each other.

As illustrated above, the layouts of the upper overlay key patterns included in the pair of third upper overlay key structures UOK3a and UOK3b, respectively, may be substantially the same as each other. Particularly, layouts of the upper overlay key patterns included in fourth and fifth overlay key groups 140b and 150b of the third upper overlay key structure UOK3b may be substantially the same as layouts of the lower overlay key patterns included in fourth and fifth upper overlay key groups 140a and 150a of the third upper overlay key structure UOK3a.

A pair of fourth upper overlay key groups 140a and 140b may be formed by an exposure process using a pair of fourth upper overlay mark groups UOM4a and UOM4b disposed at a left edge of the fourth reticle R4, and a pair of fifth upper overlay key groups 150a and 150b may be formed by an exposure process using a pair of fifth upper overlay mark groups UOM5a and UOM5b disposed at a right edge of the fourth reticle R4.

The pair of fourth upper overlay key structures UOK4a and UOK4b may be disposed at opposite sides, respectively, of the second center line CL2.

Components of the pair of fourth upper overlay key structures UOK4a and UOK4b, respectively, may be arranged by the same layout. Hereinafter, only the fourth upper overlay key structure UOK4a is described.

The fourth upper overlay key structure UOK4a may include a sixth upper overlay key group 160a. The sixth upper overlay key group 160a may include seventeenth, eighteenth, nineteenth and twentieth upper overlay key sub-groups 161a, 162a, 163a and 164a. The seventeenth, eighteenth, nineteenth and twentieth upper overlay key sub-groups 161a, 162a, 163a and 164a may be disposed to be rotated by 90 degrees in a clockwise direction about a twelfth center point C12. That is, the sixth upper overlay key group 160a may have 90-degree rotational symmetry.

In example embodiments, the seventeenth upper overlay key sub-group 161a may include seventeenth-1, seventeenth-2, seventeenth-3, seventeenth-4, seventeenth-5 and seventeenth-6 upper overlay key patterns 161_1, 161_2, 161_3, 161_4, 161_5 and 161_6. Each of the seventeenth-1, seventeenth-2, seventeenth-3, seventeenth-4, seventeenth-5 and seventeenth-6 upper overlay key patterns 161_1, 161_2, 161_3, 161_4, 161_5 and 161_6 may extend in the second direction D2, and the seventeenth-1, seventeenth-2, seventeenth-3, seventeenth-4, seventeenth-5 and seventeenth-6 upper overlay key patterns 161_1, 161_2, 161_3, 161_4, 161_5 and 161_6 may be spaced apart from each other in the third direction D3.

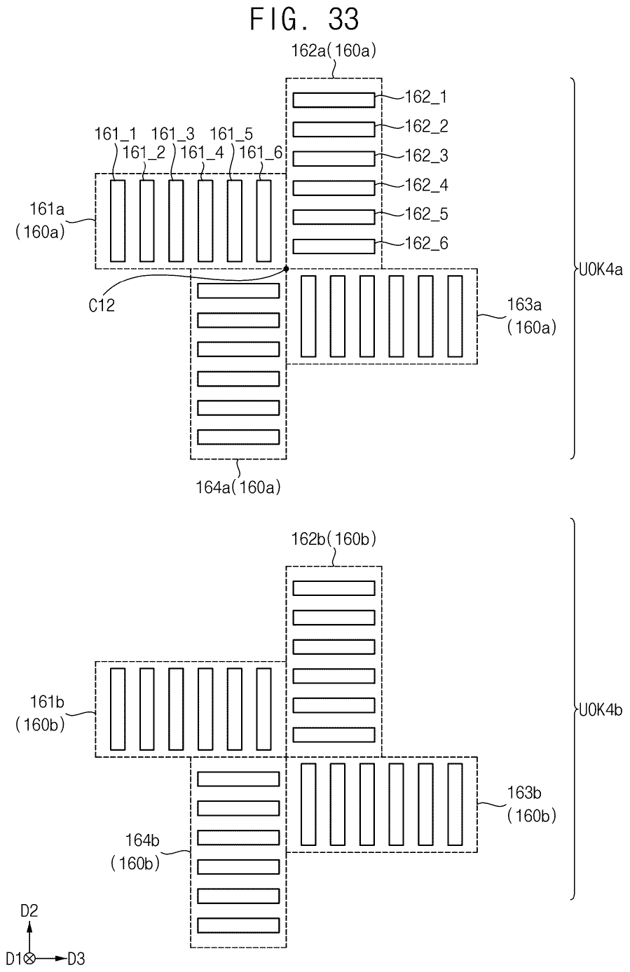

In example embodiments, the eighteenth upper overlay key sub-group 162a may include eighteenth-1, eighteenth-2, eighteenth-3, eighteenth-4, eighteenth-5 and eighteenth-6 upper overlay key patterns 162_1, 162_2, 162_3, 162_4, 162_5 and 162_6. The eighteenth upper overlay key sub-group 162a may be disposed to be rotated by 90 degrees in a clockwise direction with respect to the seventeenth upper overlay key sub-group 161a about the twelfth center point C12. For example, referring to FIG. 33, the eighteenth-1, eighteenth-2, eighteenth-3, eighteenth-4, eighteenth-5 and eighteenth-6 upper overlay key patterns 162_1, 162_2, 162_3, 162_4, 162_5 and 162_6 of the eighteenth upper overlay key sub-group 162a may be disposed to be rotated by 90 degrees in a clockwise direction with respect to the seventeenth-1, seventeenth-2, seventeenth-3, seventeenth-4, seventeenth-5 and seventeenth-6 upper overlay key patterns 161_1, 161_2, 161_3, 161_4, 161_5 and 161_6, respectively, of the seventeenth upper overlay key sub-group 161a about the twelfth center point C12.

The nineteenth upper overlay key sub-group 163a may be disposed to be rotated by 90 degrees in a clockwise direction with respect to the eighteenth upper overlay key sub-group 162a about the twelfth center point C12.

The twentieth upper overlay key sub-group 164a may be disposed to be rotated by 90 degrees in a clockwise direction with respect to the nineteenth upper overlay key sub-group 163a about the twelfth center point C12.

A pair of sixth upper overlay key groups 160a and 160b may be formed by an exposure process using a pair of sixth upper overlay mark groups UOM6a and UOM6b disposed at a center of the fourth reticle R4.

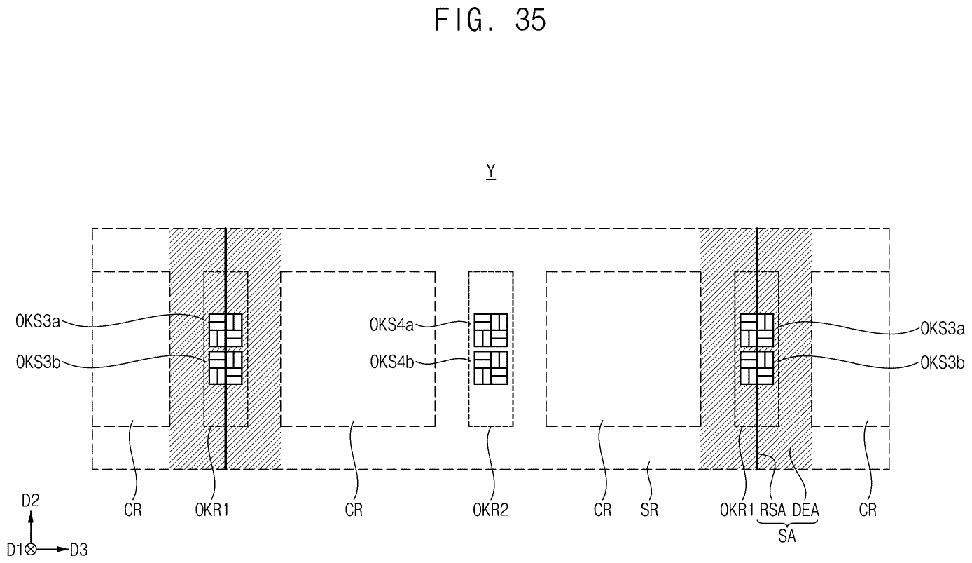

FIGS. 35 to 37 show that the pair of third lower overlay key structures LOK3a and LOK3b and the pair of third upper overlay key structures UOK3a and UOK3b are ideally aligned with each other, and the pair of fourth lower overlay key structures LOK4a and LOK4b and the pair of fourth upper overlay key structures UOK4a and UOK4b are ideally aligned with each other, such that no overlay error occurs.

In this case, the pair of third lower overlay key structures LOK3a and LOK3b and the pair of third upper overlay key structures UOK3a and UOK3b do not overlap each other in the first direction D1. Likewise, the pair of fourth lower overlay key structures LOK4a and LOK4b and the pair of fourth upper overlay key structures UOK4a and UOK4b do not overlap each other in the first direction D1.

The pair of third lower overlay key structures LOK3a and LOK3b and the pair of third upper overlay key structures UOK3a and UOK3b may form a pair of third overlay key structures OKS3a and OKS3b. Particularly, the third lower overlay key structures LOK3a and the third upper overlay key structures UOK3a may form the third overlay key structure OKS3a, and the third lower overlay key structures LOK3b and the third upper overlay key structures UOK3b may form the third overlay key structure OKS3b.

Likewise, the pair of fourth lower overlay key structures LOK4a and LOK4b and the pair of fourth upper overlay key structures UOK4a and UOK4b may form a pair of fourth overlay key structures OKS4a and OKS4b. Particularly, the fourth lower overlay key structures LOK4a and the fourth upper overlay key structures UOK4a may form the fourth overlay key structure OKS4a, and the fourth lower overlay key structures LOK4b and the fourth upper overlay key structures UOK4b may form the fourth overlay key structure OKS4b.

FIG. 38 is an enlarged plan view of an overlay key structure illustrating a method of manufacturing a semiconductor device in accordance with example embodiments.

Referring to FIG. 38, the first center point C1 of the first lower overlay key group 10a and the second center point C2 of the second lower overlay key group 20a do not coincide with each other, but offset to each other.

Likewise, the fourth center point C4 of the first upper overlay key group 40a and the fifth center point C5 of the second upper overlay key group 50a do not coincide with each other, but offset to each other.

Likewise, the seventh center point C7 of the fourth lower overlay key group 110a and the eighth center point C8 of the fifth lower overlay key group 120a do not coincide with each other, but offset to each other.

Likewise, the tenth center point C10 of the fourth upper overlay key group 140a and the eleventh center point C11 of the fifth upper overlay key group 150a do not coincide with each other, but offset to each other.

While example embodiments have been particularly shown and described, it will be understood by one of ordinary skill in the art that variations in form and detail may be made therein without departing from the spirit and scope of the claims.

What is claimed is:

1. A semiconductor device comprising:
a substrate including chip regions and a scribe lane region surrounding the chip regions;
a mold on the scribe lane region of the substrate, the mold having insulation layers and sacrificial layers alternately and repeatedly stacked in a first direction perpendicular to an upper surface of the substrate; and
a pair of overlay key structures at opposite sides, respectively, of a center line penetrating through a center of the mold, each of the pair of overlay key structures including a lower overlay key structure and an upper overlay key structure, the lower overlay key structure at least partially penetrating through the mold, and the upper overlay key structure being on the lower overlay key structure.

2. The semiconductor device of claim 1, wherein:
the pair of overlay key structures include a first overlay key structure and a second overlay key structure,
the first overlay key structure includes a first lower overlay key structure and a first upper overlay key structure,
the second overlay key structure includes a second lower overlay key structure and a second upper overlay key structure,
the first lower overlay key structure includes first lower overlay key patterns,
the first upper overlay key structure includes first upper overlay key patterns,
the second lower overlay key structure includes second lower overlay key patterns,
the second upper overlay key structure includes second upper overlay key patterns,
a planar layout of the first lower overlay key patterns is substantially the same as a planar layout of the second lower overlay key patterns, and
a planar layout of the first upper overlay key patterns is substantially the same as a planar layout of the second upper overlay key patterns.

3. The semiconductor device of claim 1, wherein the chip regions are spaced apart from each other in a second direction and a third direction, the second direction being parallel to the upper surface of the substrate, and the third direction being parallel to the upper surface of the substrate and crossing the second direction, and
wherein the mold is disposed between and spaced apart from ones of the chip regions adjacent to each other in the third direction by the same distance.

4. The semiconductor device of claim 3, wherein the center line extends in the third direction, and the pair of overlay key structures are disposed at the opposite sides, respectively, of the center line in the second direction.

5. The semiconductor device of claim 1, wherein each of the insulation layers includes silicon oxide, and each of the sacrificial layers includes silicon nitride.

6. A semiconductor device comprising:
a mold on an overlay key region of a substrate, the mold having insulation layers and sacrificial layers alternately and repeatedly stacked in a first direction perpendicular to an upper surface of the substrate; and
a pair of lower overlay key structures disposed in a second direction parallel to the upper surface of the substrate, each of the pair of lower overlay key structures at least partially penetrating through the mold; and
a pair of upper overlay key structures disposed in the second direction, corresponding to the pair of lower overlay key structures, respectively, each of the upper overlay key structures being on the mold,
wherein:
the pair of lower overlay key structures include a first lower overlay key structure and a second lower overlay key structure,
the first lower overlay key structure includes a first lower overlay key group and a second lower overlay key group,
the first lower overlay key group includes first, second, third and fourth lower overlay key sub-groups disposed having 90-degree rotational symmetry in a clockwise direction about a first center point,
the second lower overlay key group includes fifth, sixth, seventh and eighth lower overlay key sub-groups having 90-degree rotational symmetry in the clockwise direction about a second center point,
the first to fourth lower overlay key sub-groups are radially arranged to be spaced apart from the first center point by a first distance, and
the fifth to eighth lower overlay key sub-groups are radially arranged to be spaced apart from the second center point by a second distance less than the first distance.

7. The semiconductor device of claim 6, wherein the first and second center points are offset to each other.

8. The semiconductor device of claim 6, wherein each of the first, third, fifth and seventh lower overlay key sub-groups includes first lower overlay key patterns spaced apart from each other in a third direction parallel to the upper surface of the substrate and crossing the second direction, each of the first lower overlay key patterns extending in the second direction, and
each of the second, fourth, sixth and eighth lower overlay key sub-groups includes second lower overlay key patterns spaced apart from each other in the second direction, each of the second lower overlay key patterns extending in the third direction.

9. The semiconductor device of claim 6, wherein:
the pair of upper overlay key structures include a first upper overlay key structure and a second upper overlay key structure,
the first upper overlay key structure includes a first upper overlay key group and a second upper overlay key group,
the first upper overlay key group includes first, second, third and fourth upper overlay key sub-groups having 90-degree rotational symmetry in the clockwise direction about a third center point,
the second upper overlay key group includes fifth, sixth, seventh and eighth upper overlay key sub-groups having 90-degree rotational symmetry in the clockwise direction about a fourth center point,
the first to fourth upper overlay key sub-groups are radially arranged to be spaced apart from the third center point by a third distance, and
the fifth to eighth upper overlay key sub-groups are radially arranged to be spaced apart from the fourth center point by a fourth distance less than the third distance.

10. The semiconductor device of claim 9, wherein the third and fourth center points are offset to each other.

11. The semiconductor device of claim 9, wherein each of the first, third, fifth and seventh upper overlay key sub-groups includes first upper overlay key patterns spaced apart from each other in a third direction parallel to the upper surface of the substrate and crossing the second direction, each of the first upper overlay key patterns extending in the second direction, and
each of the second, fourth, sixth and eighth upper overlay key sub-groups includes second upper overlay key patterns spaced apart from each other in the second direction, each of the second upper overlay key patterns extending in the third direction.

12. The semiconductor device of claim 6, wherein each of the insulation layers includes silicon oxide, and each of the sacrificial layers includes silicon nitride.

13. The semiconductor device of claim 6, wherein the pair of lower overlay key structures are disposed at opposite sides, respectively, of a center line penetrating through a center of the mold and extending in a third direction parallel to the upper surface of the substrate and crossing the second direction, and
wherein the pair of upper overlay key structures are disposed at the opposite sides, respectively, of the center line.

14. The semiconductor device of claim 6, wherein the substrate includes a plurality of shot regions, each of the shot regions including a reference shot area and a double exposure area, and
wherein the overlay key region is disposed in the double exposure area.

15. A semiconductor device comprising:
a substrate including shot regions, each of the shot regions including a reference shot area and a double exposure area;
a first mold on the double exposure area of the substrate, the first mold having first insulation layers and first sacrificial layers alternately and repeatedly stacked in a first direction perpendicular to an upper surface of the substrate;
a first pair of overlay key structures, each of the first pair of overlay key structures including a first lower overlay key structure and a first upper overlay key structure, the first lower overlay key structure at least partially penetrating through the first mold, and the first upper overlay key structure being on the first lower overlay key structure;
a second mold on the reference shot area of the substrate, the second mold having second insulation layers and second sacrificial layers alternately and repeatedly stacked in the first direction; and
a second pair of overlay key structures, each of the second pair of overlay key structures including a second lower overlay key structure and a second upper overlay key structure, the second lower overlay key structure at least partially penetrating through the second mold, and the second upper overlay key structure being on the second lower overlay key structure.

16. The semiconductor device of claim 15, wherein:
the first lower overlay key structure includes a first lower overlay key group and a second lower overlay key group, the first lower overlay key group being spaced apart from a first center point by a first distance and having 90-degree rotational symmetry, and the second lower overlay key group being spaced apart from a second center point by a second distance less than the first distance and having 90-degree rotational symmetry,
the first upper overlay key structure includes a first upper overlay key group and a second upper overlay key group, the first upper overlay key group being spaced apart from a third center point by a third distance and having 90-degree rotational symmetry, and the second upper overlay key group being spaced apart from a fourth center point by a fourth distance less than the third distance and having 90-degree rotational symmetry, and
the second lower overlay key structure includes a third lower overlay key group being spaced apart from a fifth center point by a fifth distance and having 90-degree rotational symmetry, and the second upper overlay key structure including a third upper overlay key group being spaced apart from a sixth center point by a sixth distance having 90-degree rotational symmetry.

17. The semiconductor device of claim 16, wherein the first center point and the second center point are offset to each other, and the third center point and the fourth center point are offset to each other.

18. The semiconductor device of claim 15, wherein:
the first lower overlay key structure includes a first lower overlay key group and a second lower overlay key group, the first lower overlay key group having 180-degree rotational symmetry, and the second lower overlay key group having an arrangement substantially identical to an arrangement by rotating the first lower overlay key group 90 degrees in a clockwise direction,
the first upper overlay key structure includes a first upper overlay key group and a second upper overlay key group, the first upper overlay key group having 180-degree rotational symmetry, and the second upper overlay key group having an arrangement substantially identical to an arrangement by rotating the first upper overlay key group 90 degrees in the clockwise direction,
the second lower overlay key structure includes a third lower overlay key group having 90-degree rotational symmetry, and
the second upper overlay key structure includes a third upper overlay key group having 90-degree rotational symmetry.

19. The semiconductor device of claim 18, wherein a first center point of the first lower overlay key group and a second center point of the second lower overlay key group are offset to each other, and a third center point of the first upper overlay key group and a fourth center point of the second upper overlay key group are offset to each other.

20. The semiconductor device of claim 15, wherein
the first lower overlay key structures respectively included in the first pair of overlay key structures are disposed at opposite sides, respectively, of a first center line penetrating through a center of the first mold and extending in a second direction parallel to the upper surface of the substrate, and the first upper overlay key structures respectively included in the first pair of overlay key structures are disposed at the opposite sides, respectively, of the first center line,
the second lower overlay key structures respectively included in the second pair of overlay key structures are disposed at opposite sides, respectively, of a second center line penetrating through a center of the second mold and extending in the second direction, and the second upper overlay key structures respectively included in the second pair of overlay key structures are disposed at the opposite sides, respectively, of the second center line.
